(19) United States
(12) Patent Application Publication
(10) Pub. No.: US 2016/0281251 A1
(43) Pub. Date: Sep. 29, 2016

(54) Electrodeposition of Copper

(71) Applicant: Enthone Inc., West Haven, CT (US)

(72) Inventors: Vincent Paneccasio, West Haven, CT (US); Kyle Whitten, West Haven, CT (US); John Commander, West Haven, CT (US); Richard Hurtubise, West Haven, CT (US); Eric Rouya, West Haven, CT (US)

(21) Appl. No.: 15/037,267

(22) PCT Filed: Nov. 25, 2014
(86) PCT No.: PCT/US2014/067403

§ 371 Date: May 17, 2016

Related U.S. Application Data
(60) Provisional application No. 61/908,491, filed on Nov. 25, 2013.

(51) Int. Cl. C25D 3/38; H05K 3/18; H05K 1/09; H01L 21/768; H01L 23/532; H01L 21/288; H05K 3/42

(52) U.S. Cl. CPC C25D 3/38; H01L 21/2885; H05K 3/188; H05K 3/423; H01L 21/76879; H01L 23/53228; H05K 1/09

(57) ABSTRACT

In electrolytic copper plating, an aqueous composition comprising a source of copper ions and at least one alkylene or polyalkylene glycol monoether which is soluble in the aqueous phase and has molecular weight not greater than about 500 for improving the efficacy of other additives such as, for example, levelers and suppressors; and a related plating method.

### FIELD OF THE INVENTION

The present invention generally relates to compositions and methods for electrolytic copper deposition for a variety of applications. The invention in one aspect relates to additives incorporated into copper plating baths in order to improve delivery of functional compounds across substrates onto which copper is electrolytically deposited.

### BACKGROUND OF THE INVENTION

Electrolytic copper deposition often involves the deposition of Cu from Cu plating baths which contain functional additives such as suppressors, levelers, accelerators and other additives which affect the deposition characteristics and mechanisms. Non-limiting examples of Cu plating applications which employ functional additives include Cu plating in the manufacture of integrated circuits, through-silicon via (TSV), printed wiring boards (PWB), and wafer level packaging (WLP), for example.

One challenge in many Cu plating applications is that a high surface tension may not provide rapid, uniform distribution of components such as functional additives across the surface of a substrate to be plated.

An example of additive-assisted Cu plating is damascene Cu plating in the production of semiconductor integrated circuit (IC) devices such as computer chips. In view of the increasing circuit speed and circuit density associated with these devices, there has been substantial downward scaling of interconnect feature sizes in ultra-large scale integration (ULSI) and very-large scale integration (VLSI) structures. The trend to smaller device sizes and increased circuit density requires decreasing the dimensions of interconnect features and increasing their density. An interconnect feature is a feature such as a via or trench formed in a dielectric substrate which is then filled with metal, typically copper, to render the interconnect electrically conductive. Copper has been introduced to replace aluminum to form the connection lines and interconnects in semiconductor substrates. Copper, having better conductivity than any metal except silver, is the metal of choice since copper metallization allows for smaller features and uses less energy to pass electricity. In damascene processing, interconnect features of semiconductor IC devices are metallized using electrolytic copper deposition.

In the context of semiconductor integrated circuit device manufacture, substrates include patterned dielectric films on semiconductor wafer or chip substrates such as, for example, silicon or low-κ dielectric films on silicon or silicon-germanium. Typically, a wafer has layers of integrated circuitry, e.g., processors, programmable devices, memory devices, and the like, built into one or more layers of dielectric on a semiconductor substrate. Integrated circuit (IC) devices have been manufactured to contain sub-micron vias and trenches that form electrical connections between layers of interconnect structure (via) and between devices (trench). These features typically have dimensions on the order of about 200 nanometers or less.

One conventional semiconductor manufacturing process is the copper damascene system. Specifically, this system begins by etching the circuit architecture into the substrate's dielectric material. The architecture is comprised of a combination of the aforementioned trenches and vias. Next, a barrier layer is laid over the dielectric to prevent diffusion of the subsequently applied copper layer into the substrate's junctions, followed by physical or chemical vapor deposition of a copper seed layer to provide electrical conductivity for a sequential electrochemical process. Copper to fill into the vias and trenches on substrates can be deposited by plating (such as electroless or electrolytic), sputtering, plasma vapor deposition (PVD), and chemical vapor deposition (CVD). It is generally recognized that electrochemical deposition is the best method to apply copper since it is more economical than other deposition methods and can flawlessly fill into the interconnect features (often called “bottom up” growth or superfilling). After the copper layer has been deposited, excess copper is removed from the facial plane of the dielectric by chemical mechanical polishing, leaving copper in only the etched interconnect features of the dielectric. Subsequent layers are produced similarly before assembly into the final semiconductor package.

Copper plating methods must meet the stringent requirements of the semiconductor industry. For example, copper deposits must be uniform and capable of flawlessly filling the small interconnect features of the device, for example, with openings of 100 nm or smaller.

Electrolytic copper systems have been developed which rely on so-called “superfilling” or “bottom-up growth” to deposit copper into various aspect ratio features. Superfilling involves filling a feature from the bottom up, rather than at an equal rate on all its surfaces, to avoid seams and pinching off that can result in voiding. Multi-part systems consisting of a suppressor and an accelerator as additives have been developed for superfilling, as in Paneccasio et al., U.S. Pat. No. 8,388,824.

Satisfactory distribution of components becomes particularly critical in superfilling submicron interconnect features of a semiconductor integrated circuit device. The problem becomes progressively more difficult as the size of the interconnects has become much finer in recent years, e.g., to <100 nm, <50 nm and <20 nm, and continues to become even finer, i.e., <10 nm, e.g., ˜7 nm.

### SUMMARY OF THE INVENTION

Briefly, therefore, the invention is directed to a composition for electroplating copper comprising a source of metal ions and an additive which is an alkylene or polyalkylene glycol ether of lower molecular weight or mixtures thereof, and related plating method. Preferably, the ether has a molecular weight of less than 500 g/mole.

Briefly, therefore, the invention is directed to an aqueous composition comprising a source of copper ions and at least one alkylene or polyalkylene glycol ether which is soluble in the aqueous phase and has molecular weight not greater than about 500 for improving the efficacy of other additives such as, for example, levelers and suppressors

In one embodiment, the ether has the following general Structure (1) or (2):

R¹O[CH₂CHR²O]ₙR³ Structure (1)
wherein R¹ is a substituted or unsubstituted alkyl, cycloalkyl, or aryl group;
R² is H or a substituted or unsubstituted alkyl group having, for example, from 1 to 3 carbon atoms;
n is an integer such that the compound is not so large that it interferes with plating, and is such that it is compatible with the bath; in one embodiment, n is from an integer from 1 to 7, such as from 1 to 6, from 1 to 5, or from 1 to 4; and
R³ is H.

R¹O[CH₂CHR²O]ₙ[CH₂CHR⁴O]ₘR³ Structure (2)
Wherein R1 is a substituted or unsubstituted alkyl, cycloalkyl, or aryl group;
R² is H or a substituted or unsubstituted alkyl group having, for example, from 1 to 3 carbon atoms;
R⁴ is H or a substituted or unsubstituted alkyl group having, for example, from 1 to 3 carbon atoms, R⁴ being different from R²;
n and m are an integers such that the compound is not so large that it interferes with plating, and is such that it is compatible with the bath; in one embodiment, n and m are integers from 1 to 7, such as from 1 to 6, from 1 to 5, or from 1 to 4; and
R³ is H.

In another aspect, the invention is directed to a plating method for electrodeposition of copper on a substrate comprising a copper-based or cobalt-based surface, the process comprising establishing an electrolytic circuit comprising a power source, an anode in contact with an electrodeposition solution and a cathode comprising the substrate surface and in contact with said electrodeposition solution; and passing an electrolytic current through said circuit to deposit copper on said cathode; wherein the electrodeposition composition has the above-described glycol ether.

Other objects and features will be in part apparent and in part pointed out hereinafter.

### BRIEF DESCRIPTION OF THE DRAWINGS

FIG. 1 plots surface tension vs. surface age (i.e., time) in dynamic surface tension tests of a baseline makeup low acid electrolytic plating solution (MULA) and of solutions in which tripropylene glycol n-butyl ether (TPB) has been added to a MULA solution in concentrations ranging from 1 g/L to 10 g/L;

FIG. 2 comprises dynamic surface tension plots similar to those of FIG. 1 for a makeup low acid copper plating solution (MULA) solution, a MULA solution to which a suppressor has been added and MULA solutions containing a suppressor and two different concentrations of TPB;

FIG. 3 comprises dynamic surface tension plots similar to those of FIGS. 1 and 2 comparing a MULA solution containing a suppressor vs. a MULA solution containing a suppressor and TPB, and a MULA solution containing 10 g/L TPB but no suppressor;

FIG. 4 comprises dynamic surface tension plots similar to those of FIGS. 1-3 comparing MULA solutions containing varying concentrations of tripropylene glycol methyl ether (TPM), tripropylene glycol propyl ether (TPP) and tripropylene glycol n-butyl ether (TPB);

FIG. 5 is a plot of dynamic contact angle for a MULA solution containing a suppressor and a MULA solution containing a suppressor and TPB;

FIG. 6 plots dynamic contact angle for MULA solutions of tripropylene glycol methyl ether (TPM), tripropylene glycol n-propyl ether (TPP) and TPB;

FIG. 7 shows chronopotentiometric polarization curves for a MULA plating solution containing an accelerator and a suppressor, and a plating solution identical to the first except that it also contained TPB;

FIG. 8 comprises cross-sectional photomicrographs of trenches filled by electrodeposition from the several plating solutions of Example 8;

FIG. 9 shows a series of bar graphs indicating the static surface tension as measured for various compositions consisting of a MULA solutions respectively containing TPM, TPP, TPB, dipropylene glycol propyl ether (DPP), dipropylene glycol butyl ether (DPB), and propylene glycol butyl ether (PB);

FIG. 10 shows dynamic surface tension curves for a MULA solution containing a suppressor and four additional formulations consisting of MULA compositions containing the suppressor and varying concentrations of TPP;

FIG. 11 shows dynamic surface tension curves similar to those of FIG. 10 except that the hydrotrope used in the tests was TPB instead of TPP and the range of concentrations is different;

FIG. 12 shows dynamic surface tension curves for similar to those of FIGS. 10 and 11 except that the hydrotrope used in the tests was propylene glycol n-butyl ether;

FIG. 13 displays selected dynamic surface tension curves from FIG. 10-12 which provide a comparison between a MULA solution containing a suppressor and MULA solutions containing the suppressor and either TPB, propylene glycol butyl ether (PB) or TPP at indicated concentrations;

FIG. 14 shows dynamic surface tension curves similar to those of FIG. 13 but for different combinations of hydrotrope and hydrotrope concentration;

FIG. 15 comprises bar graphs similar to those of FIG. 9, in this case comparing static surface tension of a MULA bath containing TPB with MULA baths containing three different hydrotropes each consisting of an ethoxylated TPB;

FIG. 16 plots static surface tension vs. wetter (hydrotrope) concentration for solutions respectively containing TPB and three different hydrotropes consisting of ethoxylated TPB;

FIG. 17 displays chronopotentiometric polarization curves for solutions containing an accelerator, suppressor, leveler and TPB that has been ethoxylated a varying discreet EO/TPB ratios;

FIG. 18 plots surface tension against surface age for dynamic surface tension tests on solutions comprising a low copper electrolyte containing copper sulfate (40 g/L Cu⁺⁺), sulfuric acid (10 g/L), chloride ion (50 ppm), and varying concentrations of a reaction product of TPB and 1.5 moles ethylene oxide;

FIG. 19 reproduces polarization curves from chronopotentiometric tests of a low copper acid plating solution containing an alkoxylated amine suppressor (200 ppm) and a low copper solution containing the suppressor and an alkoxylated butanol (7.5 g/L);

FIG. 20 plots dynamic surface tension against surface age for the two low copper electrolyte solutions, each containing an alkoxylated amine suppressor (200 ppm), and further containing an alkoxylated butanol, the same solutions to which FIG. 19 relates;

FIG. 21 shows a series of surface tension plots for solutions comprising a low copper electrolyte solution containing copper sulfate, sulfuric acid, chloride ion, and varying concentrations of the alkoxylated butanol referred to in the previous figures; and

FIG. 22 shows additional plots of surface tension vs. surface age for various plating solutions comprising low acid electrolyte containing varying combinations of suppressor and hydrotrope.

### DETAILED DESCRIPTION OF THE INVENTION

The present invention is directed to compositions and methods for depositing metals such as copper or copper alloys. The compositions of the invention include an additive which assists in rapid and uniform dispersion of functional additives across the surface of the substrate being plated. The additive compound is an alkylene glycol monoether or a polyalkylene glycol monoether. Such additive compounds are understood to serve as hydrotropes to associate with other functional additives and distribute them uniformly across a substrate. As used herein, the term “hydrotrope” refers to a glycol ether that promotes rapid and uniform distribution of functional additives across the cathode surface, including the surfaces within trenches and vias. It does not necessarily designate an additive that enhances the solubility of another additive, though in some instances it may serve that purpose as well. For example, it may tend to increase solubility of a suppressor in the aqueous phase.

The method of the present invention is accomplished by incorporating certain hydrotrope compounds into an electrolytic plating solution. These compounds include certain alkylene glycol and polyalkylene glycol ethers. One class of preferred additives is low molecular weight polyalkylene glycol ethers.

Surprisingly, the inventors have discovered that the addition of certain low molecular weight hydrotrope compounds to a copper electrolyte yields advantages which can be attributed to rapid and uniform distribution of functional components such as suppressors and accelerators across the substrate surface and reduction in surface tension as illustrated in the examples and figures herein. The hydrotrope compounds are generally lower molecular weight and have a molecular weight, for example, below 500 g/mole, such as less than 350 g/mole, e.g., 117 to 500 or 117 to 350 g/mole. In some preferred embodiments of the invention, the molecular weight of the hydrotrope compound is less than 250 g/mole, e.g., 117 to 250 g/mole.

Hydrotrope compounds useful in the compositions and methods of the invention include alkylene and polyalkylene glycol ethers having the following general Structure (1) or (2):

R¹O[CH₂CHR²O]ₙR³ Structure (1)
wherein R¹ is a substituted or unsubstituted alkyl, cycloalkyl, or aryl group;
R² is H or a substituted or unsubstituted alkyl group having, for example, from 1 to 3 carbon atoms;
n is an integer such that the compound is not so large that it interferes with plating, and is such that it is compatible with the bath; in one embodiment, n is from an integer from 1 to 7, such as from 1 to 6, from 1 to 5, or from 1 to 4; and
R³ is H.

R¹O[CH₂CHR²O]ₙ[CH₂CHR⁴O]ₘR³ Structure (2)
Wherein R1 is a substituted or unsubstituted alkyl, cycloalkyl, or aryl group;
R² is H or a substituted or unsubstituted alkyl group having, for example, from 1 to 3 carbon atoms;
R⁴ is H or a substituted or unsubstituted alkyl group having, for example, from 1 to 3 carbon atoms, R⁴ being different from R²;
n and m are an integers such that the compound is not so large that it interferes with plating, and is such that it is compatible with the bath; in one embodiment, n and m are integers from 1 to 7, such as from 1 to 6, from 1 to 5, or from 1 to 4; and
R³ is H.

One currently preferred subgenus is limited to monoethers having these structures.

In Structure (1) n is preferably from 2 to 6, more preferably 2 to 5, and in Structure (2), the sum of n+m is preferably from 2 to 6, more preferably 2 to 5.

In certain alternative embodiments of Structure (1), R² is a compatible hetero substituent, for example, CH₂OH. In certain alternative embodiments of Structure (2), R² and/or R⁴ may be compatible hetero substituents, for example, CH₂OH, or otherwise.

In various preferred embodiments of the invention, the hydrotrope additive is an alkylene or polyalkylene glycol ether having the following general Structure (3):

R¹O[CH₂CHR²O]ₙR³ Structure (3)
wherein R¹ is substituted or unsubstituted alkyl group having from 1 to 6 carbon atoms;
R² is methyl;
R³ is hydrogen; and
n is an integer between 1 and 3, inclusive.

Particularly preferred polyalkylene glycol ethers of Structure (III) are compounds wherein R¹ is n-propyl or n-butyl, R² is methyl, R⁴ is hydrogen, and n is 1 or 3. For example, a particularly preferred additive in the invention is tripropylene glycol butyl ether, as in Structure (4).

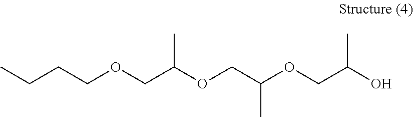 [SMILES: CCCCOCC(C)OCC(C)OCC(C)O]

Such compound is available, for example, from Dow Chemical under the trade name Dowanol® TPnB. Although depicted as the n-butyl ether, the commercial product includes a mix of isomers comprising n-butyl and other butyl radical configurations, i.e., sec-butyl, isobutyl and/or t-butyl.

Other particularly preferred additives of the invention include tripropylene glycol n-propyl ether (TPP, Structure (5) and propylene glycol n-butyl ether (PB, Structure (6)).

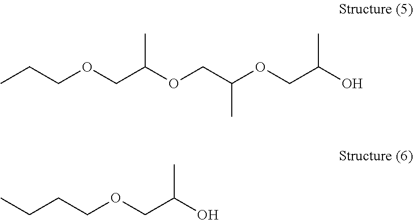

These two glycol ethers are commercially available from Dow Chemical under the trademark Dowanol® TPnP and Dowanol® PnB, respectively. The propyl ethers also comprise a mixture of n-propyl and isopropyl.

In further embodiments of the invention, a mixture of glycol ether additives may be utilized in the copper plating bath. Thus, it may be advantageous to combine two or more propylene glycol ethers, for example, or to combine a propylene glycol ether with an ethylene glycol ether.

The glycol ether additive is generally present in the electrolytic copper plating bath at a concentration of at least about 1 g/L, e.g., 1 to 20 g/L or 1 to 5 g/L. Preferably the glycol ether additive is present in a concentration of at least about 3 g/L or at least about 5 g/L, and more typically range from about 5 to about 20 g/L. The concentration of some of these glycol ethers in certain embodiments is maintained below a maximum such as about 20 g/L, because above such maximum, the glycol ether additive can interfere with Cu filling of features. More preferred ranges of glycol ether concentration are from about 5 to about 15 g/L or from about 5 and about 10 g/L. Too high of a concentration also tends to lower cloud point, such that there can be separation of the components in the electrolyte.

It is thought that the glycol ether additive of the present invention lowers the surface tension of the solution to a value which approaches that of the Cu substrate. Where a cobalt seed layer is used instead of a Cu seed layer, the surface tension of the plating solution is preferably matched as nearly as feasible with the surface tension of the Co substrate. Lowering the surface tension helps to promote rapid and uniform distribution of components such as functional additives across the substrate, displaces air bubbles on the surface, and allows the plating bath and its components to penetrate features of the substrate. It is a challenge to deliver functional additive components of plating solutions instantaneously to the smaller features of today's substrates; and the challenge is expected to grow as such features are expected to be smaller with each advancing technology node. Furthermore, as the size of substrates continues to increase, e.g., 300 mm or 450 mm silicon wafers, problems associated with uniform delivery of plating solution and its components across substrates are exacerbated.

A wide variety of low molecular weight monofunctional alkylene and polyalkylene glycol ethers suitable for use in the present invention are commercially available. A preferred additive of this invention, tripropylene glycol n-butyl ether, is sold under the trade name Dowanol® TPnB as a mixture of isomers, referred to herein as TPB.

One electrolytic deposition composition of the present invention comprises the glycol ether, a source of Cu ions, an acid, water, and one or more functional additives. For filling submicron features of a semiconductor integrated circuit device, the electrolytic deposition composition of the present invention typically comprises the glycol ether, a source of copper ions, chloride ions, an acid, an accelerator, a suppressor, and a leveler. It may further comprise more than one suppressor, or more than one accelerator, or more than one leveler.

The composition of the invention can be used for electrodeposition of copper in a variety of applications involved in the manufacturing of electronic circuits. For example, the composition can be used for process such as superfilling submicron interconnects in a semiconductor integrated circuit chip, filling through silicon vias (TSVs), in plating printed wiring boards and filling vias therein, and in wafer level packaging. The invention is hereafter described in the context of its use in damascene Cu plating to superfill features of silicon wafer IC substrates. The general process as well as appropriate accelerator, suppressor, and leveler additives are disclosed in issued U.S. Pat. Nos. 6,776,893; 7,303,992; 7,316,772; 8,002,962; and 8,388,824. The disclosures of these patents are expressly incorporated herein by reference. The accelerator and suppressor components in the compositions of the invention work together in a manner that advantageously enhances bottom up so-called “superfilling” of interconnect features in contrast to conformal plating.

To achieve defect-free filling, i.e., void-free and seam-free, the deposition rate in the bottom should greatly exceed the deposition rate on the side walls. For example, during copper metallization, copper deposition rate along of the bottom (i.e., bottom up or vertical growth rate) is preferably at least one order of magnitude faster than the copper deposition rate along the sidewalls (i.e. lateral or horizontal growth rate). These relative deposition rates are especially important in filling submicron features of a semiconductor integrated circuit device.

The accelerator may include an organic sulfur compound. Organic sulfur compounds currently preferred by the applicants are water soluble organic divalent sulfur compounds as disclosed in U.S. Pat. No. 6,776,893, the entire disclosure of which is expressly incorporated by reference. An accelerator which is especially preferred is 3,3′-dithiobis-1-propanesulfonic acid disodium salt, which has the following structure.

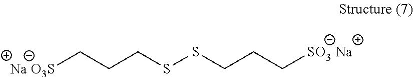

or 3-mercaptopropane sulfonic acid, sodium salt.

The organic sulfur compound may be added in a concentration between about 20 mg/L and about 200 mg/L (ppm), typically between about 40 mg/L and about 100 mg/L, such as between about 50 mg/L and 70 mg/L. In a preferred embodiment, the organic sulfur compound is 3,3′-dithiobis(1-propanesulfonic acid) disodium salt (or analog or derivative or free acid), added in a concentration of about 60 mg/L.

Suppressors typically comprise a polyethyer bonded to an alcohol moiety, as prepared, e.g., by ethoxylating the corresponding alcohol, but improved bottom-up filling can be realized by the presence in the plating solution of a suppressor comprising a polyether group covalently bonded to a base moiety, more particularly to a nitrogen-containing species. One class of applicable suppressors comprises a polyether group covalently bonded to an amine moiety. In some embodiments, the current invention employs the suppressors disclosed in Paneccasio et al. U.S. Pat. Nos. 6,776,893 or 7,303,992.

A wide variety of electrolytic copper deposition compositions are potentially applicable, including both low acid (e.g., 10 g/L), mid acid (e.g., 80 g/L), and high acid (e.g., 200 g/L) baths. Exemplary electrolytic copper plating baths include acidic copper plating baths based on, for example, copper fluoroborate, copper sulfate, and other copper metal complexes such as copper methane sulfonate and copper hydroxyethyl sulfonate. Preferred copper sources include copper sulfate in sulfuric acid solution and copper methane sulfonate in methane sulfonic acid solution.

In embodiments wherein the copper source is copper sulfate and the acid is sulfuric acid, the concentration of copper ion and acid may vary over wide limits; for example, from about 4 to about 70 g/L copper and from about 2 to about 225 g/L sulfuric acid. In this regard the compounds of the invention are suitable for use in distinct acid/copper concentration ranges, such as high acid/low copper systems, in low acid/high copper systems, low acid/low copper systems, and mid acid/high copper systems.

In other embodiments, the copper source comprises copper methanesulfonate and the acid comprises methanesulfonic acid. The use of copper methanesulfonate as the copper source allows for greater concentrations of copper ions in the electrolytic copper deposition bath in comparison to other copper ion sources.

When copper methane sulfonate is used as the source of copper ions, it is preferred to use methane sulfonic acid for acid pH adjustment. This avoids the introduction of unnecessary anions into the electrolytic deposition chemistry. When methane sulfonic acid is added, its concentration may be above about 1 g/L. It has been discovered that the electrolytic deposition composition of the present invention preferably has a low acid concentration, such as between about 1 g/L and about 50 g/L, or between about 5 g/L and about 25 g/L, e.g., about 10 g/L.

Chloride ion may also be used in the bath at a level up to on the order of no more than 100 mg/L (about 100 ppm), for example about 10 mg/L to about 90 mg/L (10 to 90 ppm), e.g., about 50 mg/L (about 50 ppm).

Exemplary plating solutions include a “low acid” solution containing copper sulfate (30-60 g/L Cu⁺⁺), sulfuric acid (5-25 g/L), and chloride ion (35-70 ppm), e.g., 40 g/L Cu⁺⁺, 10 g/L sulfuric acid, and 50 ppm chloride ion; and a “low copper” solution having the same range of acid and chloride concentration as a “low acid” solution but containing only 3 to 20 g/L, preferably 3 to 10 g/L Cu⁺⁺, e.g., 5 g/L Cu⁺⁺, 10 g/L sulfuric acid, and 50 ppm chloride ion.

In some embodiments, the current invention employs the levelers disclosed in Paneccasio et al. U.S. Pat. Nos. 8,002,962 or 8,388,824. A large variety of additives may typically be used in the bath to provide desired surface finishes and metallurgies for the copper plated metal. Usually more than one additive is used to achieve desired functions. At least two additives or three are generally used to initiate bottom-up filling of interconnect features as well as for improved metal metallurgical, physical and electrical properties (such as electrical conductivity and reliability). Additional additives (usually organic additives) include grain refiners and secondary brighteners and polarizers for the suppression of dendritic growth, improved uniformity, and defect reduction.

A “wafer,” as referred to in this invention, is a semiconductor substrate at any of the various states of manufacture in the production of integrated circuits. The standard semiconductor wafers contemplated for use in the context of some embodiments of this invention have 200, 300, or 450 mm.

Plating equipment for plating semiconductor substrates is well known and is described in the literature. The nature of the equipment is not germane to the present invention.

The bath additives are useful in combination with membrane technology being developed by various tool manufacturers. In this system, the anode may be isolated from the organic bath additives by a membrane. The purpose of the separation of the anode and the organic bath additives is to minimize the oxidation of the organic bath additives on the anode surface.

The cathode substrate and anode are electrically connected by wiring and to the power supply, or more directly to the output terminals of a rectifier which converts a.c. current to d.c. Electrons supplied in the circuit to the cathode substrate by direct or pulse current reduce copper ions in the plating solution to plate copper metal on the cathode surface. An oxidation reaction takes place at the anode. The cathode and anode may be horizontally or vertically oriented in the tank.

During operation of the electrolytic plating system, a pulse current, direct current, reverse periodic current, or other suitable current may be employed. The temperature of the electrolytic solution may be maintained using a heater/cooler whereby electrolytic solution is removed from a holding tank and flows through the heater/cooler and then is recycled to the holding tank.

Electrolysis conditions such as applied voltage, current density, solution temperature and flow condition are essentially the same as those in conventional electrolytic copper plating methods. For example, the bath temperature is typically about room temperature such as about 15 to 27° C. The electrical current density is typically up to about 20 A/dm², such as about 10 A/dm², and typically from about 0.2 A/dm² to about 6 A/dm². It is preferred to use an anode to cathode area ratio of about 1:1, but this may also vary widely, for example from on the order of 1:2 to 2:1. The process also uses mixing in the electrolytic plating tank which may be supplied by agitation or preferably by the circulating flow of recycle electrolytic solution through the tank.

The high purity of the copper deposited from the electrolytic copper plating composition of the present invention facilitates fast anneal, even at room temperature. High purity copper deposit is believed to be beneficial for electromigration resistance and thus increases the reliability of devices. At the 32 nm and the 22 nm node (i.e., where the entry dimension of the interconnect feature is 32 nm or 22 nm, respectively) and beyond, the need for more complete and uniform distribution of copper plating components and functional additives is critical. The process can be operated to fill submicron interconnect features having an entry dimension of less than 100 nm, less than 50 nm (e.g., 20 to 50 nm), <30 nm (e.g., 10 to 30 nm), <20 nm, (e.g. 10 to 20 nm), or <10 nm (e.g., 5-10 nm), at aspect ratios of a seeded feature of at least about 3:1, preferably at least about 4:1, more preferably at least about 5:1, or even greater than or equal to about 8:1.

Copper metallization upon initial deposition is in a state in which it undergoes recrystallization which typically causes individual copper grains to grow in size and which decreases the resistivity of the deposited copper. Wafer manufacturers may anneal wafers having copper metallization therein by subjecting them to temperatures of about 200° C. for about 30 minutes to stabilize crystal structure. It has been additionally discovered that the high purity copper deposited from the electrolytic copper plating composition of the present invention undergoes relatively rapid recrystallization at room temperature in which the copper deposit resistance decreases in a manner of hours.

As noted, the alkylene or polyalkylene glycol ether additive is preferably a small molecule, e.g., having a molecular weight of less than 500. Preferably, R² is alkyl, most preferably methyl. The greater proportion of PO units the molecule contains, the generally more effective it is in reducing the static and dynamic surface tension of the plating solution and thus enhancing the distribution of functional additives across the cathodic substrate surface. But increasing the number of PO units detracts from solubility and lowers cloud point. For this purpose, it is desirable that, where R²=methyl (or higher alkyl), the value of n in structures (1) and (2) is between 1 and 3, and the sum of m+n in structure (2) is between 3 and 6, more preferably between 3 and 5. The nature of R¹ also affects solubility, which generally declines with the number of carbon atoms in this substituent. Solubility is enhanced and cloud point increased by the presence of EO groups especially in a block configuration wherein one or more PO units are bonded to R¹—O and a terminal moiety of one or more EO units is bonded to the PO structure at a point remote from R¹—O. However, while EO units promote solubility, they detract from the capability of the molecule to reduce surface tension.

To enable the formulation of a plating bath having a desired concentration of the wetter additive, a satisfactory cloud point, and a desired effect on surface tension of the plating solution, it may be preferable in some applications to select a polyalkylene glycol ether of structure (2) in which R² is methyl, R⁴ is H, the value of n is 1 or 2 and the value of m+n is 3 to 6, preferably 3 to 5. Particularly desirable structures can be prepared by ethoxylation of compositions of structure (1). In the ethoxylation, the ratio of EO to structure (1) is preferably limited to between about 0.2 and about 2.0, e.g., 0.5 EO, 1.0 EO or 1.5 EO. Thus, a desired degree of ethoxylation yields a mixture of a Structure (2) species wherein R² is methyl, R⁴ is H, n is 2 or 3 and m*, the number average of values of m in the mixture, is between about 0.2 and about 0.8, or between about 0.8 and about 1.2, or between about 1.2 and about 1.8.

Where R⁴ is H, the value of m in Structure (2), and the value of m* in mixtures of structure (2) species can be still higher than the preferred values described above, but the capability of the wetting agent for promoting rapid superfilling of submicron features of a semiconductor integrated circuit device is diminished as the molecular weight increases. It may be noted that the fundamental structure of the alkylene glycol wetting agents is similar to that of the high molecular weight polyalkylene glycol ethers that are classically used as suppressors in filling submicron features of a semiconductor wafer. Thus, as the length of the polyalkylene oxide chain is increased above 5 or 6 alkylene oxide repeat units, with associated increase in molecular weight, structures (1) and (2) can begin to take on the characteristics of a suppressor and function as such in the plating bath. Although the polyalkylene glycol ether wetting agents remain relatively poor suppressors compared to the much larger polyalkylene glycol ethers commonly selected as suppressors in damascene plating, the relatively high concentrations of the wetting agent in the plating bath can begin to contribute materially to the suppression of current along the cathodic surface. While the high molecular weight suppressors have a much stronger suppressive effect per unit of concentration in the plating bath, the concentration of the low molecular weight wetting agents must be relatively much higher if they are to reduce surface tension sufficiently to materially enhance distribution of functional additives, including the suppressor, across the cathode surface. For example, the ideal concentration of a high molecular weight suppressor may typically range from only about 10 to about 500 mg/L, more typically 100 to 400 mg/L. By comparison, as explained above, the minimum concentration of the wetting agent is ordinarily at least about 1 g/L, i.e., 1000 mg/L, with a typically preferred range of 3000 to 5000 or even 10,000 or 20,000 mg/L. Such concentrations are sufficient to have a significant suppressive effect where the values of n or m+n are significantly above the preferred ranges stated above. Even at 400-600 ppm, conventional suppressors can interfere with proper gap filling of submicron features of a semiconductor integrated circuit device. The additional presence of a polyalkylene glycol ether hydrotrope, especially at high values of m and m+n, can lead to conformal plating with consequent development of seams and voids.

Although the capability of the wetting agents for reducing surface tension varies with the identity of R¹ as well as the sum of m+n and the ratio of m/n in the molecule, even the most effective wetting agents must be used at concentrations substantially higher than conventional suppressor concentrations if the wetting agents are to material affect the surface tension.

Moreover, it has been observed that, while increasing the number of ethylene oxide units in the alkylene oxide wetting agent enhances its solubility, and raises the cloud point of an electrolytic plating solution containing it, increasing the number of EO repeat units also reduces the effectiveness of the molecule as a wetting agent. The decline in unit influence of the wetting agent on the surface tension may require a further increase in the concentration of wetting agent to achieve the desired distribution of functional additives. Such increase in concentration may exacerbate the effect of the wetting agent in excessively suppressing the electrolytic current across the cathode surface. If suppression is too strong, the accelerator may no longer be effective to selectively deactivate the suppressor at the bottom of a submicron trench or via, thus compromising the capability of the plating solution for superfilling such features, and aggravating the tendency to conformal plating and consequent development of seams and voids.

It may, therefore be seen that the factors affecting selection of the alkylene oxide chain length and concentration of the wetting agent in the plating solution tend to conflict. A compound of structure (1) is effective for reducing surface tension, but has limited solubility and a low cloud point, which further decline as the value of n is increased to >3. A compound of structure (2) having a relatively longer EO chain is effective to raise solubility and cloud point and allow use of a higher concentration of wetting agent for reducing surface tension, but raises the risk of oversuppression and void formation, while aa compound of structure (2) having a relatively short EO chain length, may have limited solubility and lower the solution cloud point, but serve better on a per unit basis to reduce surface tension and achieve desired distribution of functional additives at relatively low wetting agent concentrations that avoid excessive suppression. For most applications, the values of n in structure (1) and m+n in structure (2) have been found optimal in the 3-5 range as summarized and further detailed above.

Particularly preferred suppressors for use in the composition and process of the invention are described in U.S. Pat. No. 7,303,992, incorporated herein by reference. The preferred suppressors comprise a polyether bonded to the nitrogen of a nitrogen-containing species. It is particularly preferred that the polyether comprises a combination of propylene oxide (PO) repeat units and ethylene oxide (EO) repeat units in a PO:EO ratio between about 1:9 and about 9:1, and that the suppressor compound as a whole have a molecular weight between 1000 and 30,000. Particularly preferred suppressors comprise tetraalkoxylated alkylene diamines. In these and other alkoxylated amine suppressors, the molecular weight is preferably between about 1000 and about 10,000 and the PO:EO ratio is preferably between about 1.5:8.5 to 8.5:1.5, 3:7 to 7:3, or 2:3 to 3:2. Concentration of alkoxylated amine suppressors in the electrolytic plating solution is preferably between about 40 mg/L and about 250 mg/L.

The alkylene glycol component of the plating solution is believed to associate with the suppressor by hydrogen bonding with water, and thereby function as a carrier which enhances the distribution of the suppressor across the cathode surface.

Typical alkylene glycol and polyalkylene glycol monoethers that conform to structure (1), and may be used in the novel electrolytic plating solution, include propylene glycol ethers such as propylene glycol methyl ether, dipropylene glycol methyl ether, tripropylene glycol methyl ether, propylene glycol n-propyl ether, propylene glycol n-butyl ether, dipropylene glycol n-butyl ether, and tripropylene glycol n-butyl ether. Ethylene glycol ethers are less preferred but can also be used. These include, for example, diethylene glycol ethyl ether, diethylene glycol methyl ether, diethylene glycol n-butyl ether (commercially available, e.g., as Butyl Carbitol (Dow)), ethylene glycol propyl ether, and ethylene glycol n-butyl ether (available, e.g., as Butyl Cellosolve (Dow)). Particularly preferred among these are tripropylene glycol n-propyl ether (TPP) and tripropylene glycol n-butyl ether (TPB). The propylene and polypropylene glycol ethers are generally preferred to the ethylene glycol ethers.

However, in the commercially available alkylene and polyalkylene glycol monoethers listed above, the value n in structure (1) is either 2 or 3. In response to the discovery that enhanced solubility and cloud point can achieved using a polyalkylene glycol ether of structure (2) wherein R⁴ is H and m is 1 or 2, the present invention further comprises reacting an alkylene glycol ether with ethylene oxide to increase the value of m, thus producing a mixture wherein m*, the number average value of m is in a preferred range as stated above.

Although embodiments of structure (2) in which R⁴ is other than H are relatively rare, ethoxylation is also effective to increase the solubility and cloud point of such species. More particularly, an alkylene glycol ether of structure (2) wherein both R² and R⁴ are alkyl, or where R² is H and R⁴ is alkyl, may be reacted with ethylene oxide in an EO structure (2) ratio in a range of 0.2 to 2.0, e.g., 0.5 to 2.0, or 1.0 to 2.0, more specifically 0.2 to 0.8, 0.8 to 1.2, or 1.2 to 2.0 to produce a product of structure (8):

R¹O[CH₂CHR²O]ₙ[CH₂CHR⁴O]ₘ[CH₂CH₂O]ₚR³ Structure (8)

wherein R² is H or substituted or unsubstituted alkyl, R⁴ is substituted or unsubstituted alkyl, R³, m, and n are as defined above, and p is an integer such that the molecular weight of structure (8) is not greater than 500. This alternative embodiment further encompasses a mixture comprising molecules of structure (8) having varying values of p wherein p*, the number average value of p in the mixture is such that the number average molecular weight of the structure (8) mixture is not greater than 500, preferably not greater than about 300.

Preferably, p* is between 0.2 and 2.0, or 0.5 and 2.0, more specifically between 0.2 and 0.8, between 0.8 and 1.2, or between 1.2 and 2.0.

Particularly preferred hydrotropes are produced where one mole of an alkylene glycol ether of structure (1) is reacted with either 0.2 to 0.8 moles (preferably about 0.5 mole), 0.8 to 1.2 moles, (preferably about 1.0 moles), or between 1.2 and 2 moles (preferably about 1.5 moles) of ethylene oxide. Reaction with 0.2 to 0.8 moles ethylene oxide yields a mixture of structure (1) and structure (2) wherein m*, the number average value of m in the mixture (taken as zero in structure (1)) is between about 0.2 and about 0.8. Reaction with 0.8 to 1.2 moles of ethylene oxide yields a mixture of structure (2) species wherein m* is between 0.8 to 1.2. A reaction with 1.2 to 2 moles alkylene oxide yields a mixture of structure (2) species in which m* is between 1.2 and 2.

The present invention is particularly directed to a novel process for electrodeposition of copper on a substrate comprising a semiconductor integrated circuit device comprising submicron features. In the process, an electrolytic circuit is established comprising a power source, an anode in contact with an electrodeposition solution and a cathode comprising a seed layer on the substrate and in contact with the electrodeposition solution. Where the power source is a.c., the circuit further comprises a rectifier for converting the current to d.c. An electrolytic current is passed through the circuit to deposit copper on the cathode. The electrodeposition solution comprises a source of copper ions, a suppressor, and one or more glycol ethers or alkoxylated glycol ethers as variously defined herein which serve as hydrotropes and/or wetting agents.

Based on the description above and the working examples below, acid copper plating solutions are formulated to exhibit a dynamic surface tension of not greater than about 55 dynes/cm at 25° C. and a static surface tension of not greater than about 50 dynes/cm at 25 dynes/cm at 25° C. Further in accordance with the invention, copper plating baths may be formulated having a dynamic surface tension not materially greater than the static surface tension, e.g., in the range of 35 to 45 dynes/cm at 25° C.

### Example 1

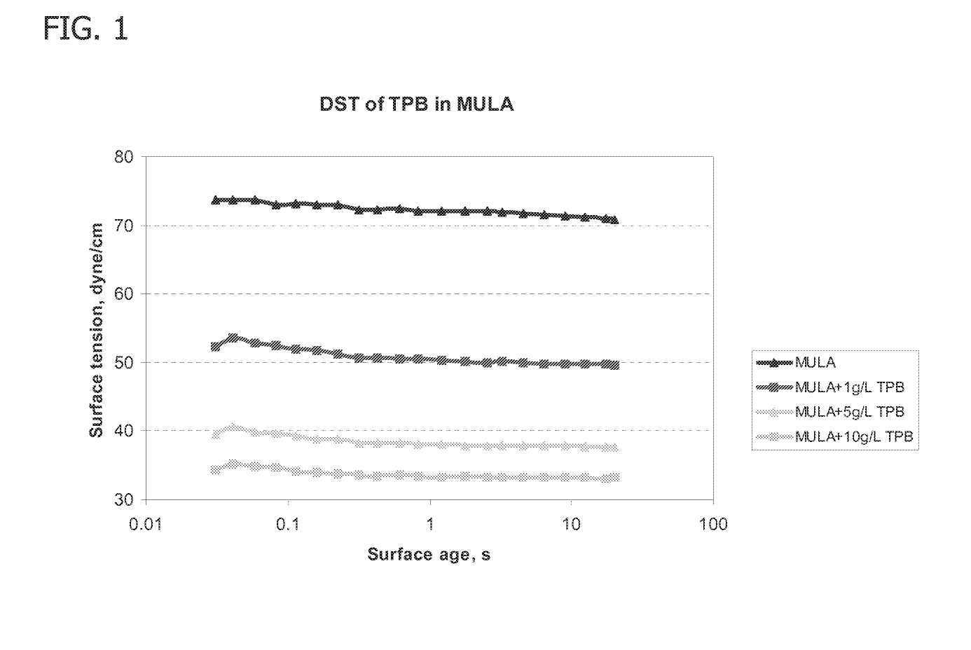

The dynamic surface tension of tri(propylene glycol) butyl ether (TPB) was measured at various concentrations in a low acid Cu plating make up electrolyte (MULA), which contained sulfuric acid (10 g/L), chloride ion (50 ppm) and copper sulfate in a concentration that provides Cu ion in a concentration of 40 g/L. The results are shown in FIG. 1.

### Example 2

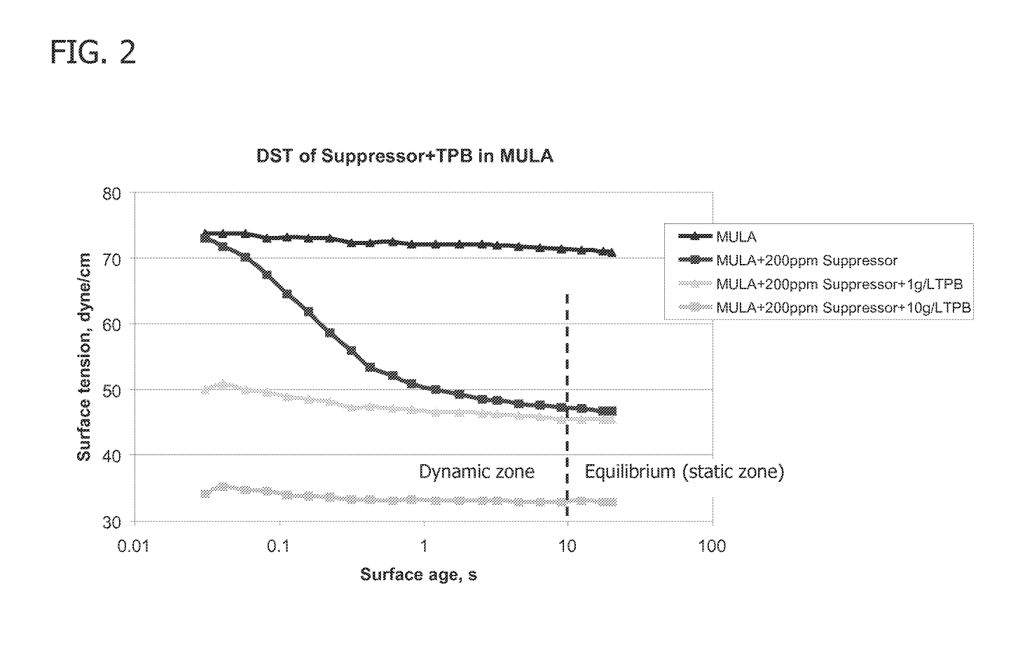

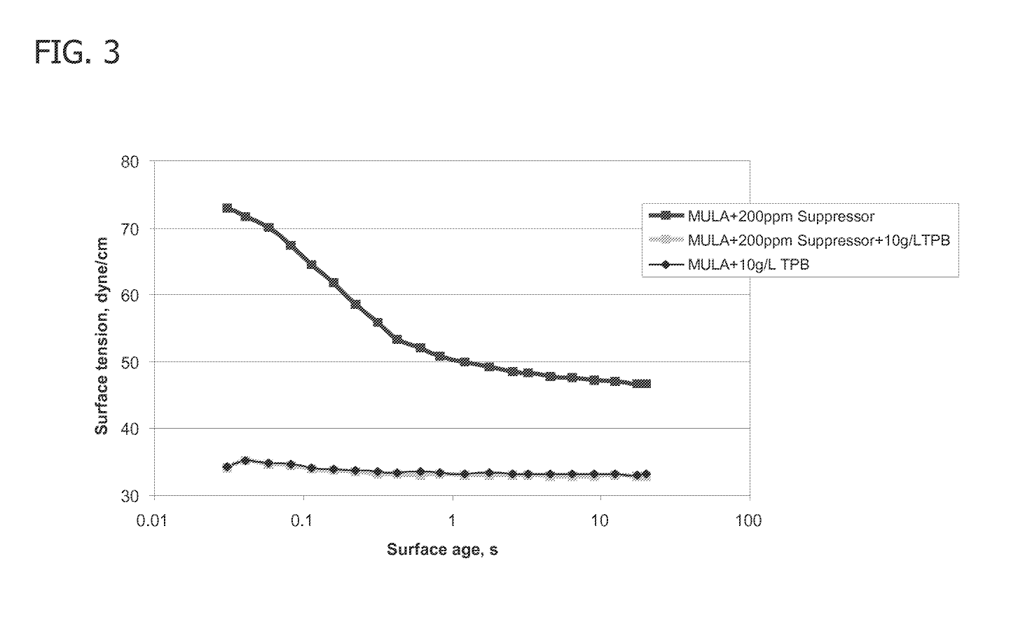

The dynamic surface tension of TPB was measured at various concentrations in a low acid Cu plating make up electrolyte (MULA) containing a tetraalkoxylated ethylenediamine suppressor. The results are shown in FIGS. 2 and 3. The addition of 10 g/L TPB significantly reduces both dynamic and static surface tension. In the suppressor (200 ppm)+TPB mixture, the TPB is the dominating influence on surface tension.

### Example 3

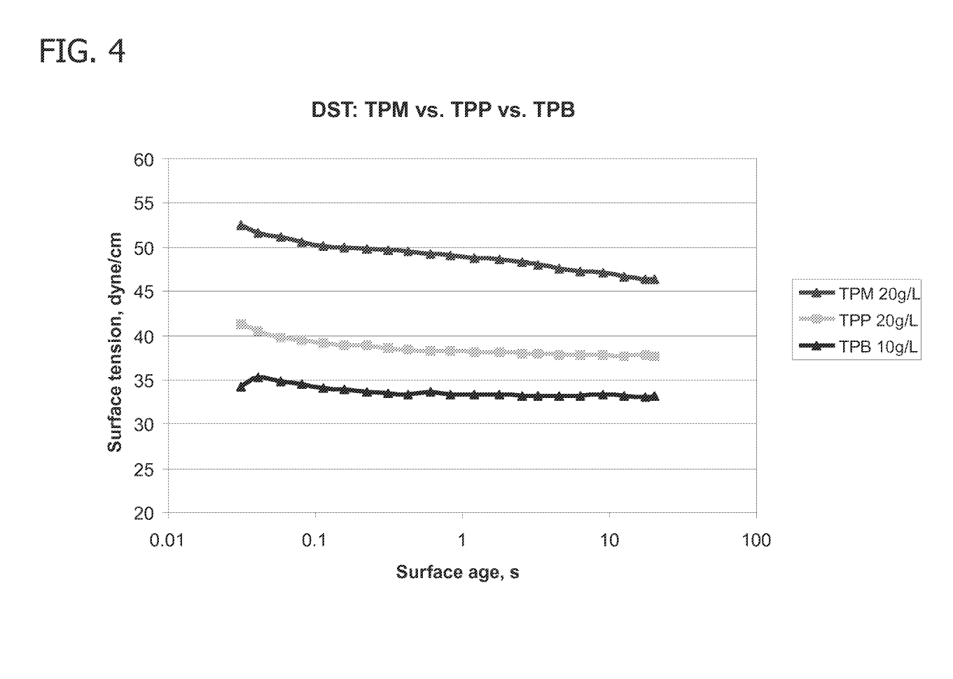

The dynamic surface tension imparted to a MULA solution by TPB was measured in comparison to TPM (tri(propylene glycol) methyl ether) and TPP (tri(propylene glycol) propyl ether). The results are shown in FIG. 4. TPB imparts the lowest surface tension of the three

### Example 4

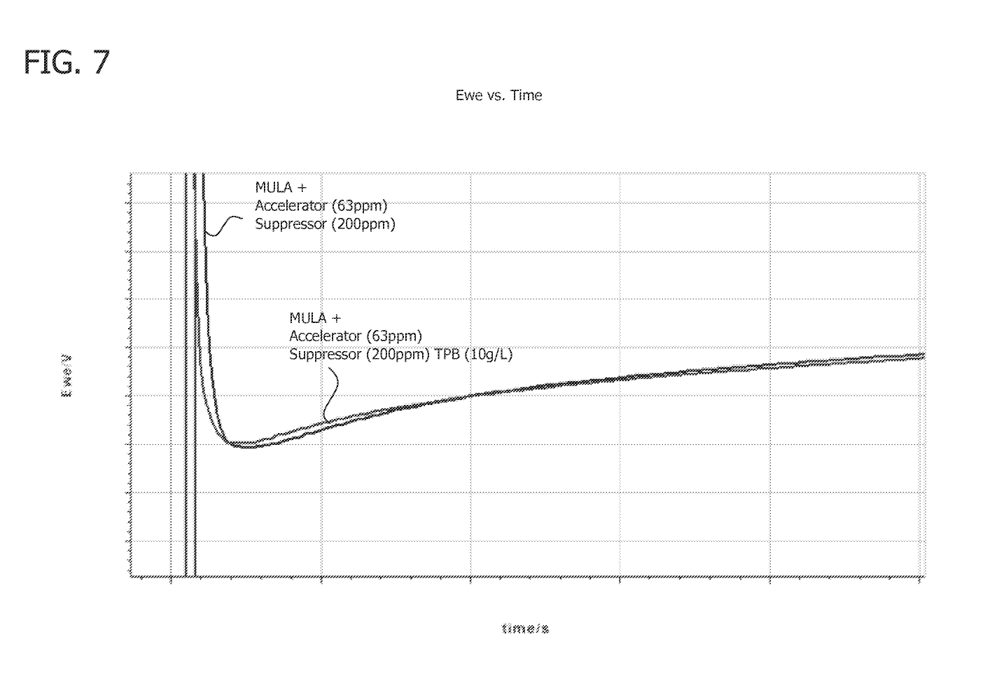

Comparative chronopotentiometry tests were conducted on electrolytic plating solutions. The first was a MULA plating solution consisting of CuSO₄ (40 g/L Cu⁺⁺), sulfuric acid (10 g/L), and chloride ion (50 ppm), an SPS accelerator (63 mg/L), and an alkoxylated amine suppressor (200 mg/L). The second plating solution was identical to the first except that it also contained tripropylene glycol n-butyl ether (10 g/L). The polarization curves are reproduced in FIG. 7. It may be seen that addition of TPB had no material effect on polarization. Thus, addition of TPB at 10 g/L neither compromised the effectiveness of the suppressor nor caused oversuppression that might have caused use of the second plating solution to trend toward conformal plating.

### Example 5

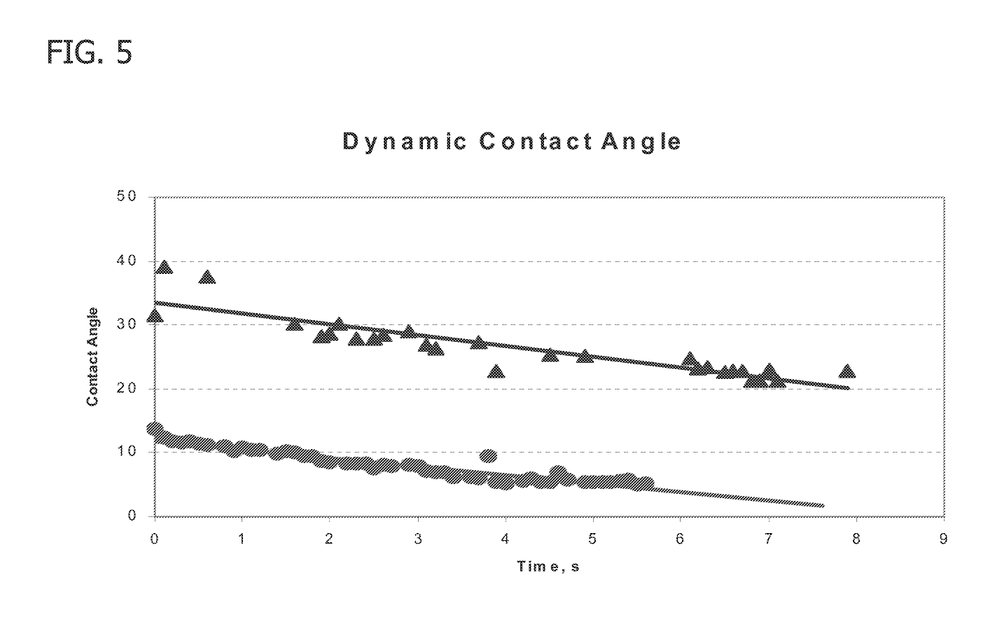

The dynamic contact angle surface tension imparted to electrolyte by TPB in the presence of an alkoxylated amine suppressor (200 ppm) was measured and is reported in FIG. 5. In FIG. 5, the triangle data represents MULA+200 ppm suppressor and the circle data represents MULA+200 ppm suppressor+10 g/L TPB. The addition of 10 g/L TPB lowers contact angle significantly, i.e., by about 20 degrees.

### Example 6

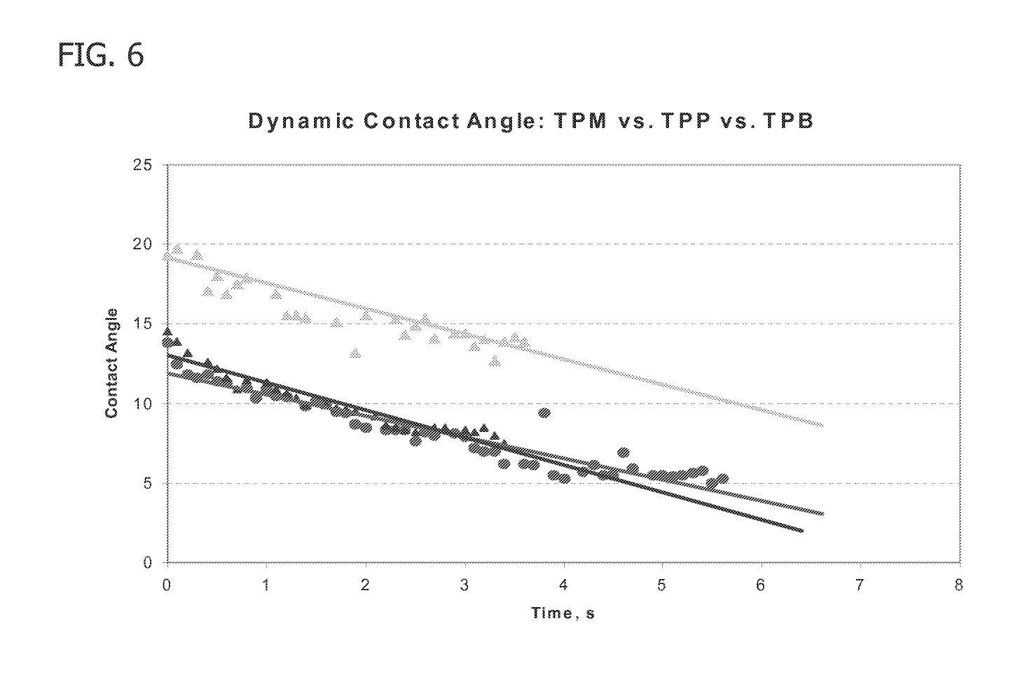

The dynamic contact angle surface tension imparted to electrolyte (MULA) by TPB in the presence of an alkoxylated amine suppressor was compared to TPP and TPM and is reported in FIG. 6. TPB and TPP are represented by the two lower curves and impart a similar dynamic contact angle to each other, which is about 5 degrees lower than TPM (the upper curve).

The results of examples 1-6 support the proposition that the hydrotrope additive used in the electrolytic plating composition and process of the invention is beneficial for getting the bath solution into features on substrates to be plated, especially small features and features with high aspect ratios. Moreover, the lower static surface tension is beneficial for wafer level plating uniformity.

### Example 7

Various tests were conducted to investigate the impact of TPM, TPP and TPB on Cu deposition impurities. The substrate was a layer of PVD Cu. The plating conditions were a waveform of 10 mA/cm2×30 s+60 mA/cm2×27 s, with a cathode rotation of 200 rpm in a 250 ml cell. Impurities were measured by secondary ion mass spectrometry. The results are summarized in Table 1

TABLE 1

| | Impurities, ppm, Cu atom | | | | | |
|---|---|---|---|---|---|---|
| Bath | C | O | S | Cl | N | Total |
| MULA only | 51.3 | 29.5 | 0.3 | 18.4 | 0.6 | 100 |
| 20 g/L TPM | 85.0 | 39.3 | 0.6 | 32.4 | 0.6 | 158 |
| 20 g/L TPP | 48.3 | 29.0 | 0.4 | 16.4 | 0.6 | 95 |
| 10 g/L TPB | 64.5 | 27.1 | 0.4 | 21.1 | 0.5 | 114 |
| Accelerator (63 ppm), | 17.2 | 21.0 | 0.3 | 0.2 | 0.2 | 39 |
| suppressor (200 ppm), leveler | | | | | | |
| (5 ppm) | | | | | | |
| Accelerator (63 ppm), | 16.0 | 23.0 | 0.2 | 0.2 | 0.2 | 40 |
| suppressor (200 ppm), leveler | | | | | | |
| (5 ppm) + 20 g/L TPM | | | | | | |
| Accelerator (63 ppm), | 26.1 | 25.4 | 0.3 | 0.2 | 0.2 | 52 |
| suppressor (200 ppm), leveler | | | | | | |
| (5 ppm) + 20 g/L TPP | | | | | | |
| Accelerator (63 ppm), | 13.9 | 22.5 | 0.3 | 0.2 | 0.2 | 37 |
| suppressor (200 ppm), leveler | | | | | | |
| (5 ppm) + 10 g/L TPB | | | | | | |
| Accelerator (63 ppm), | 15.0 | 21.8 | 0.7 | 0.9 | 0.2 | 39 |
| suppressor (200 ppm), leveler | | | | | | |
| (5 ppm) + 5 g/L TPB | | | | | | |

These results show that adding TPM, TPP and TPB has no significant impact on Cu impurity levels, and therefore is not upsetting to acceptable purity levels.

### Example 8

Various tests were conducted to investigate the impact of TPM, TPP and TPB on Cu deposition fill rate using a plating solution containing copper sulfate (40 g/L Cu⁺⁺), sulfuric acid (10 g/L), chloride ion (50) ppm, SPS accelerator (63 ppm), alkoxylated amine suppressor (200 ppm) and a leveler (4.2 ppm). At concentrations of 10 g/L TPB, 20 g/L TPP, and 20 g/L TPM in the plating solution, fill rate was reduced from 15.0 nm/s for the control electrolyte to 12.8, 9.9, and 8.2 nm/s, respectively, at concentrations of 10 g/L TPB, 20 g/L TPP, and 20 g/L TPM. At a reduced concentration of 5 g/L, the negative impact on fill speed was mitigated somewhat (13.9 nm/s). A measure of roughness (rsd) varied randomly. The results are summarized in Table 2.

TABLE 2

| | 1 | 2 | 3 | 4 |
|---|---|---|---|---|
| | no | TPM | TPP | TPB |
| plating bath | wetter | 20 g/L | 20 g/L | 10 g/L |
| 1 | 111 | 86 | 95 | 69 |
| 2 | 123 | 88 | 98 | 92 |
| 3 | 123 | 94 | 107 | 98 |
| 4 | 126 | 95 | 107 | 103 |
| 5 | 126 | 98 | 107 | 116 |
| 6 | 130 | 101 | 107 | 118 |
| 7 | 135 | 104 | 111 | 129 |
| 8 | 138 | 106 | 114 | 135 |
| 9 | 139 | 108 | 117 | 136 |
| 10 | 144 | 117 | 117 | 142 |
| 11 | 147 | 123 | 120 | 151 |
| 12 | 163 | 133 | 125 | 157 |
| ave, nm | 133 | 103 | 111 | 122 |
| rsd | 9% | 13% | 7% | 18% |
| seed, nm | 67 | 67 | 67 | 67 |
| plated, nm | 66 | 36 | 44 | 55 |
| entry time | 0.388 | 0.372 | 0.385 | 0.517 |
| plating time, | 4.412 | 4.428 | 4.415 | 4.283 |
| s | | | | |
| fill rate, nm/s | 15.0 | 8.2 | 9.9 | 12.8 |

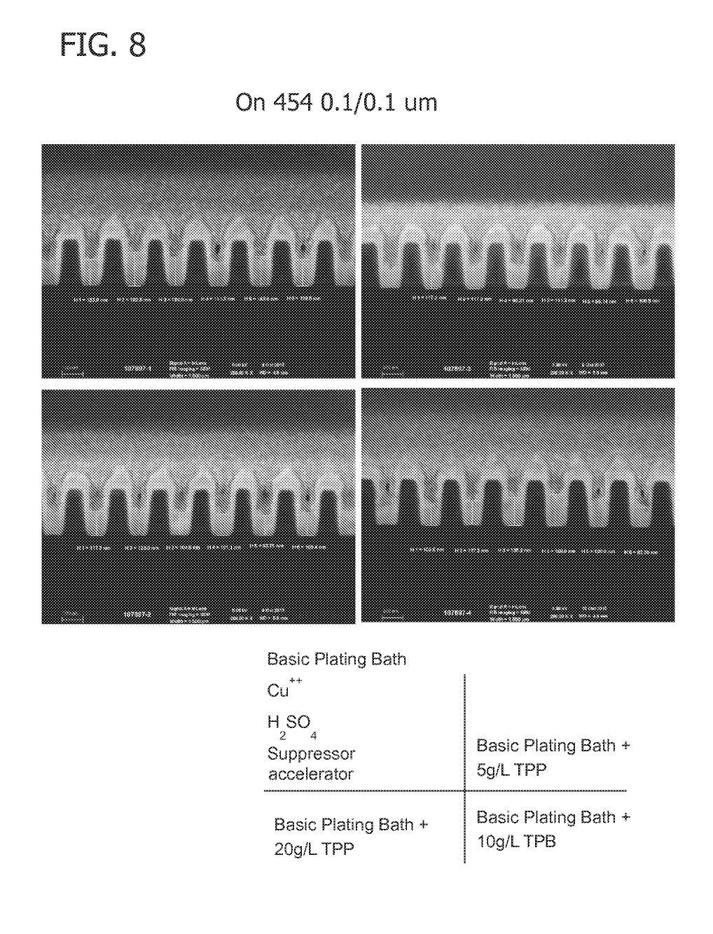

Cross-sectional photomicrographs of trenches filled by electrodeposition from the several plating solutions of this example are depicted in FIG. 8. The trenches were spaced from each other by 100 nm, and each had an entry dimension of 100 nm and a depth of 200 nm. The upper left photomicrograph is taken on trenches that were filled with a plating solution having the composition described above. The upper right photomicrograph shows the effect of adding TPP to the same solution in a concentration of 20 g/L, the lower left photomicrograph shows the effect of adding TPM to the same solution at a concentration of 20 g/Land the lower right photomicrograph shows the effect of adding TPB in a concentration of 10 g/L.

### Example 9

Static surface tension was measured for various compositions consisting of a MULA bath containing copper sulfate (40 g/L Cu⁺⁺), sulfuric acid (10 g/L), chloride ion (50 ppm) and a glycol ether. One series of four solutions contained tripropylene glycol methyl ether (TPM) at concentrations of 1 g/L, 5 g/L, 10 g/L and 20 g/L, respectively. Another series contained tripropylene glycol propyl ether (TPP), a third series contain tripropylene glycol n-butyl ether (TPB), a fourth series contained dipropylene glycol propyl ether (DPP), a fifth contained dipropylene glycol n-butyl either (DPB), and a sixth contained propylene glycol butyl ether (PB, i.e., n-butoxypropanol). In the compositions of each series, the alkylene glycol ether was respectively present in the same series of concentrations, i.e., 1 g/L, 5 g/L, 10 g/L and 20 g/L.

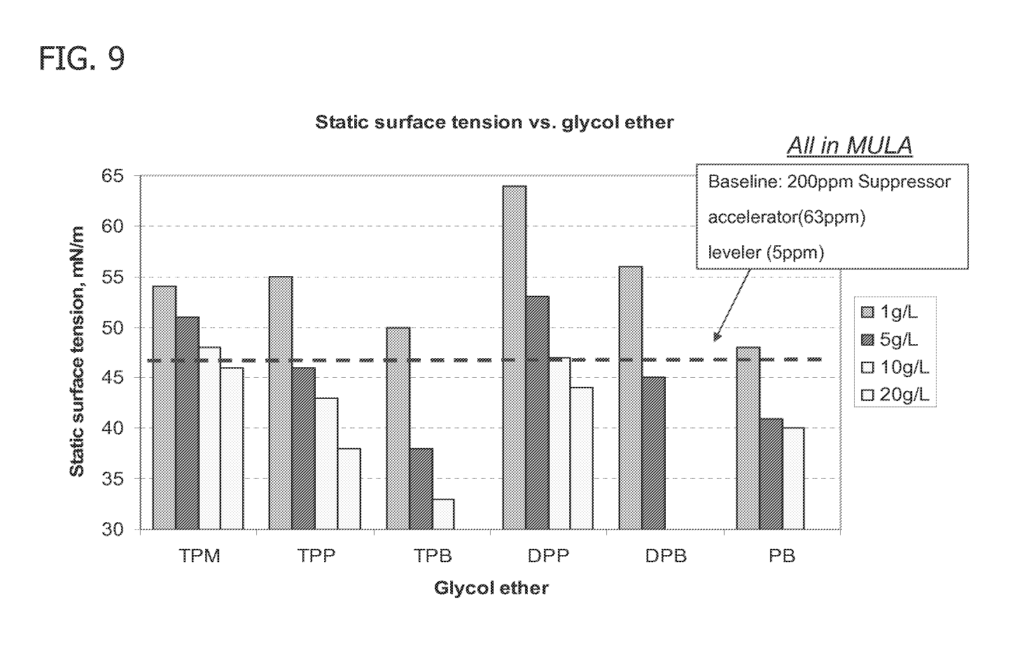

Results of static surface tension measurements are displayed as bar graphs in FIG. 9. The dotted line in FIG. 9 indicates the surface tension of a MULA plating bath having the same copper sulfate, sulfuric acid and chloride ion content of the compositions whose surface tension is indicated in the bar graphs, but which contains a tetralkoxylated ethylenediamine suppressor (200 ppm) and none of the alkylene glycol wetting agents.

### Example 10

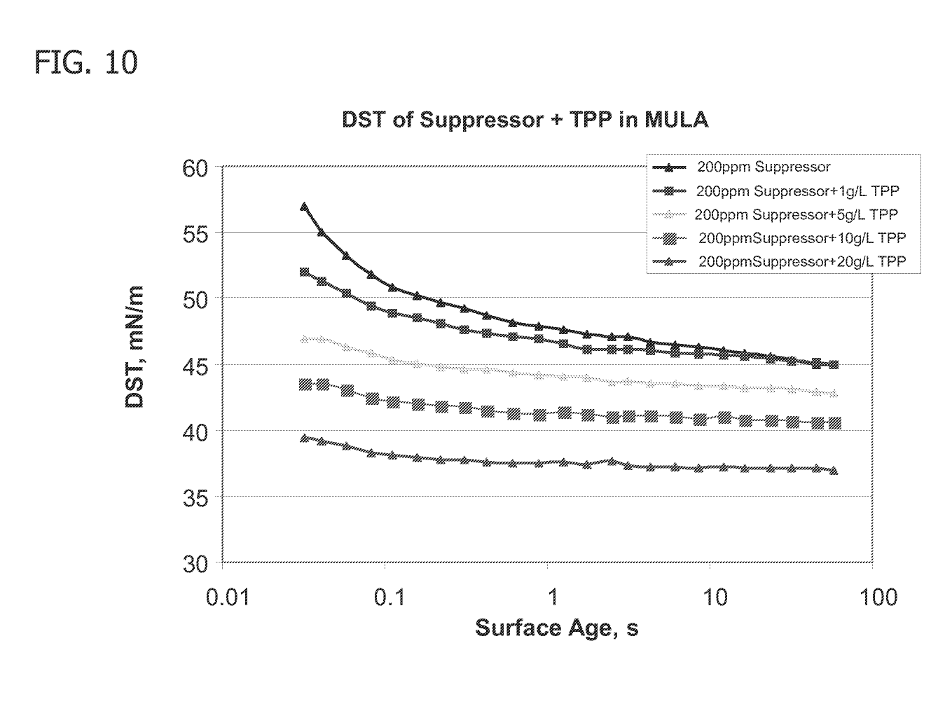

A MULA formulation was prepared comprising copper sulfate (40 g/L Cu⁺⁺), sulfuric acid (10 g/L), chloride ion (50 ppm) and a suppressor component consisting of a mixture of an alkoxylated amine (200 ppm) and an ethylene oxide/propylene oxide co-block copolymer (300 ppm). Dynamic surface tension measurements were made on the MULA formulations and four additional formulations in each of which tripropylene glycol propyl ether (TPP) had been added at concentrations of 1 g/L, 5 g/L, 10 g/L and 20 g/L, respectively. Plots of dynamic surface tension against surface age are shown in FIG. 10.

### Example 11

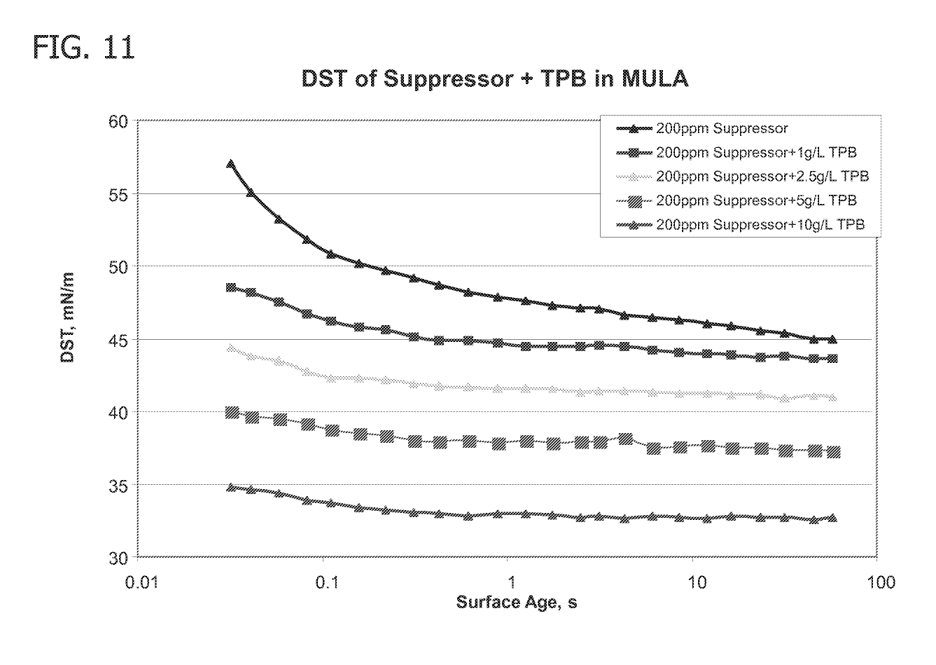

Further dynamic surface tension tests were run in the manner described in Example 10 except that the alkylene glycol ether component of the formulations was tripropylene glycol butyl ether in concentrations of 1 g/L, 2.5 g/L, 5 g/L and 10 g/L, respectively. Plots of dynamic surface tension against surface age are shown in FIG. 11.

### Example 12

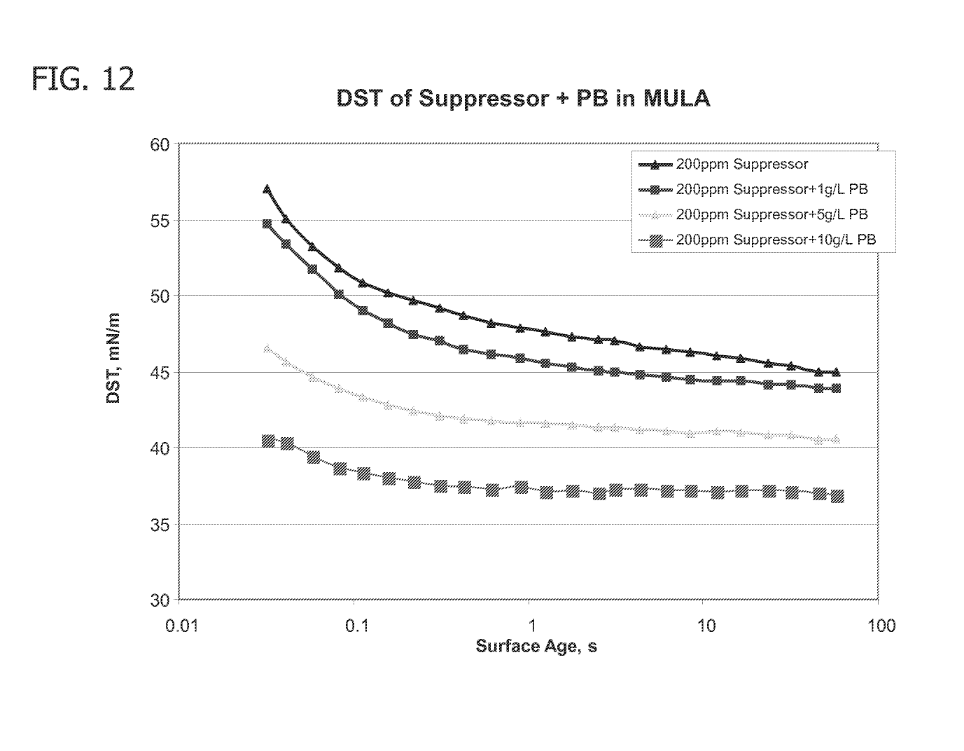

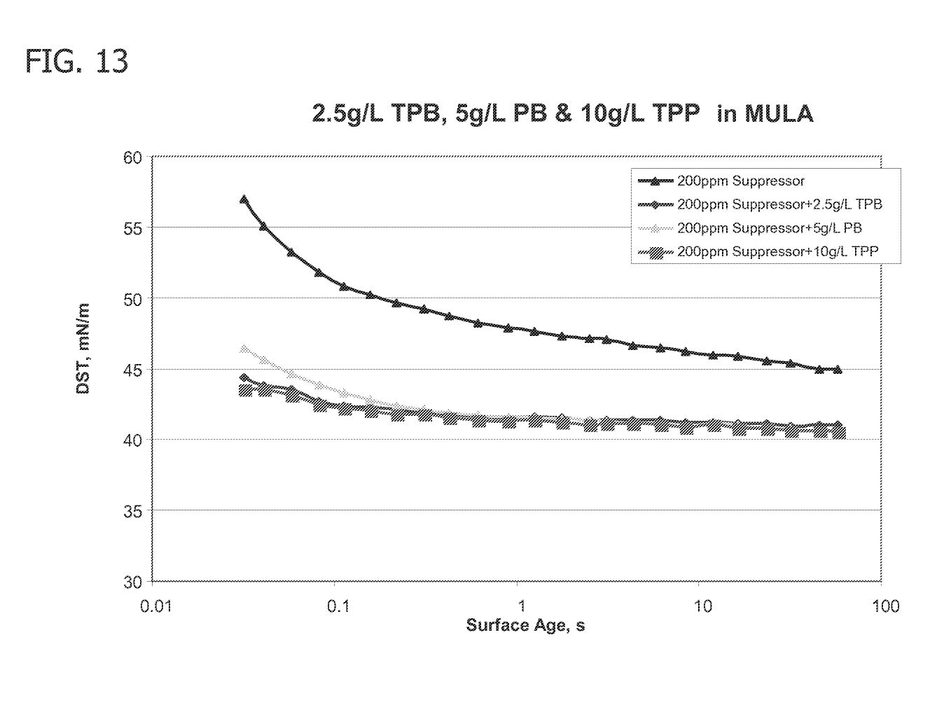

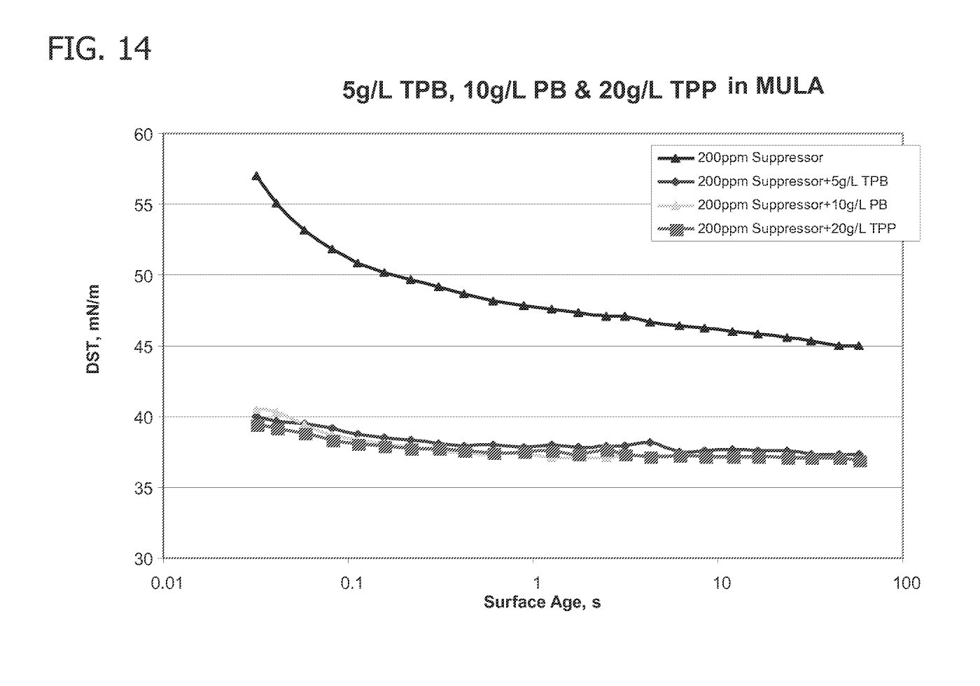

Further dynamic surface tension tests were run in the manner described in Example 10 except that only three formulations contained an alkylene glycol ether, and the alkylene glycol ether component was propylene glycol butyl ether (PB) in concentrations of 1 g/L, 5 g/L, and 10 g/L, respectively. Plots of dynamic surface tension against surface age are shown in FIG. 12. FIG. 13 plots data from Examples 10 to 12 for the baseline MULA solution, and the MULA solutions to which tripropylene glycol n-butyl ether (TPB) was added at 2.5 g/L, propylene glycol n-butyl ether (PB, i.e., n-butoxypropanol) was added at 5 g/L and tripropylene glycol propyl ether (TPP) was added at 10 g/L, respectively. FIG. 13 shows that the curves for TPB at 2.5 g/L, PB at 5 g/L and TPP at 10 g/L are almost exactly congruent. Similarly, FIG. 14 plots data from Examples 10-12 for the MULA baseline solution, and the solutions to which TPB was added at 5 g/L, PB was added at 10 g/L, and TPP was added at 20 g/L. Again, the curves for the several alkylene glycol-containing formulations were found to be substantially congruent. The data from Examples 10-12 at surface ages of 0.1 seconds, 1 second and 10 seconds are summarized in Table 3 below.

TABLE 3
All in MULA + suppressor (200 ppm)

| | | DST, | DST, | DST, |
|---|---|---|---|---|
| | | mN/m | mN/m | mN/m |
| | Bath | 0.1 s | 1 s | 10 s |
| 1 | no wetting agent | 50.8 | 47.9 | 46.3 |
| 2 | 1 g/L TPP | 48.9 | 47.0 | 45.7 |
| 3 | 5 g/L TPP | 45.3 | 44.2 | 43.4 |
| 4 | 10 g/L TPP | 42.2 | 41.3 | 40.9 |
| 5 | 20 g/L TPP | 38.1 | 37.5 | 37.2 |
| 6 | 1 g/L TPB | 46.2 | 44.8 | 44.1 |
| 7 | 2.5 g/L TPB | 42.4 | 41.6 | 41.2 |
| 8 | 5 g/L TPB | 38.8 | 37.9 | 37.7 |
| 9 | 10 g/L TPB | 33.7 | 33.0 | 32.8 |
| 10 | 1 g/L PB | 49.0 | 45.4 | 44.5 |
| 11 | 5 g/L PB | 43.3 | 41.7 | 41.0 |
| 12 | 10 g/L PB | 38.4 | 37.4 | 37.2 |

TPP—tri(propylene glycol) propyl ether
TPB—tri(propylene glycol) butyl ether
PB—propylene glycol butyl ether

### Example 13

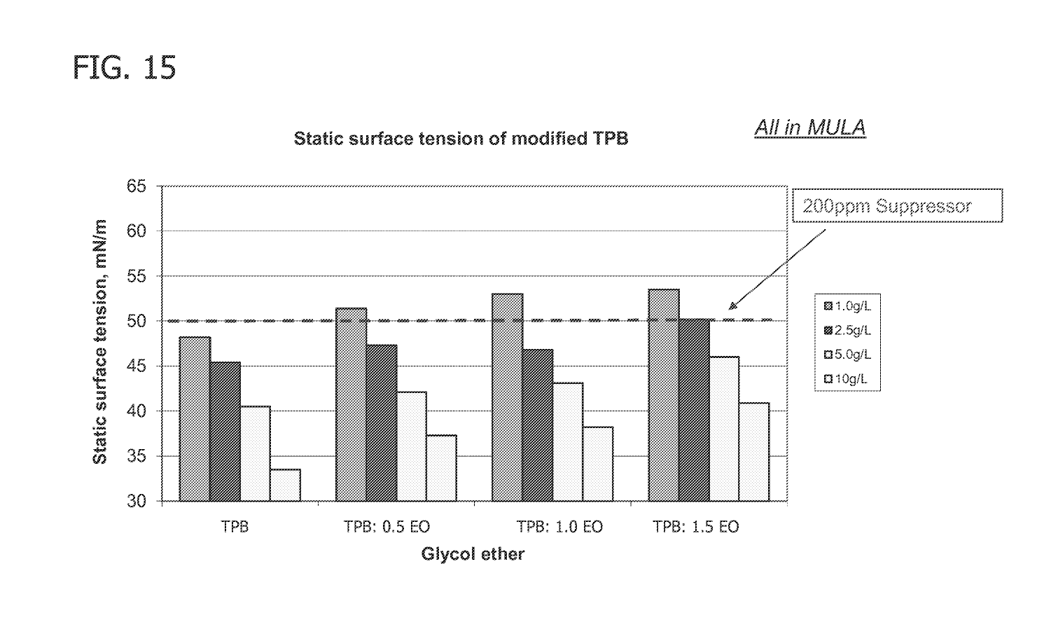

Static surface tension tests were conducted on a baseline MULA formulation consisting of copper sulfate (40 g/L Cu⁺⁺), sulfuric acid (10 g/L), and chloride ion (50 ppm), and on MULA solutions to which four different hydrotropes had respectively been added. One solution contained TPB, another contained ethoxylated TPB that had been prepared by reaction of one mole TPB with 0.5 moles ethylene oxide, a third contained an ethoxylated TPB that had been prepared by reaction of one mole of TPB with 1.0 mole of ethylene oxide, and the fourth contained an ethoxylated TPB which had been prepared by reaction of TPB with 1.5 moles ethylene oxide. Results of static surface tension measurements are displayed as bar graphs in FIG. 15. The dotted line in FIG. 15 indicates the surface tension of the baseline MULA plating bath that had the same copper sulfate, sulfuric acid and chloride ion content of the compositions whose surface tension is indicated in the bar graphs, but which contained an alkoxylated amine suppressor (200 ppm) and none of the alkylene glycol wetting agents.

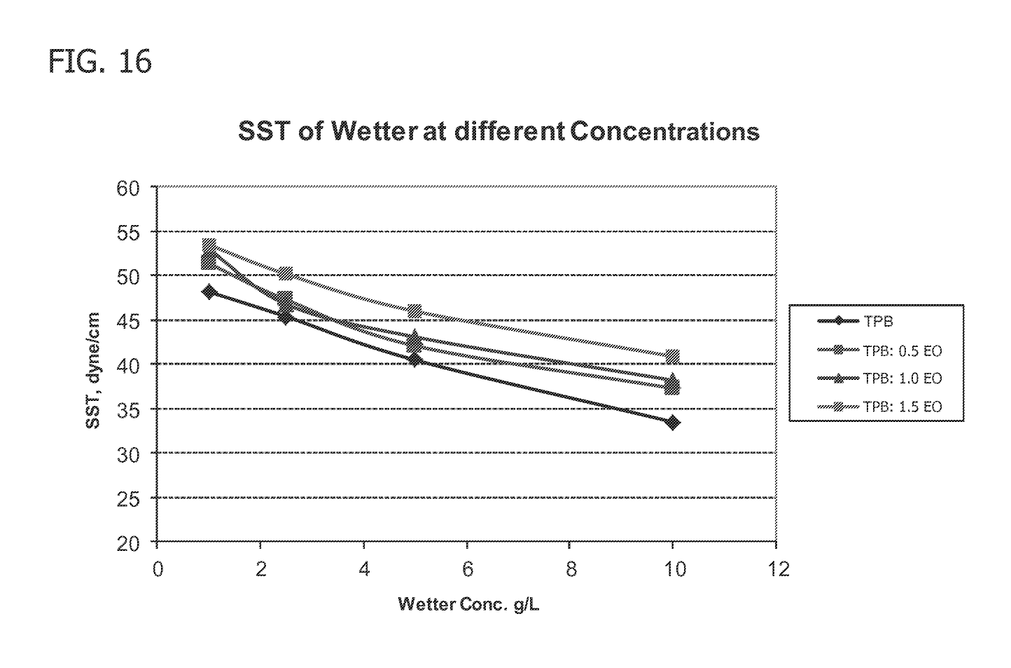

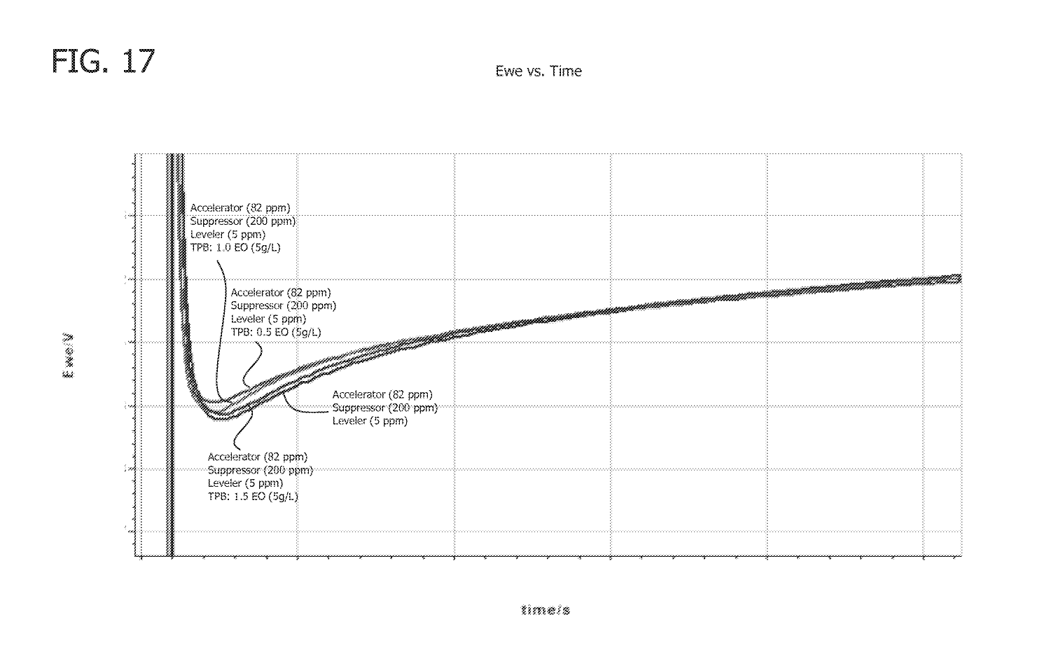

Based on the same data, FIG. 16 plots static surface tension vs. wetter concentration for TPB and ethoxylated TPB at TPB:0.5 EO, TPB:1.0 EO and TPB:1.5 EO. As illustrated in FIG. 17, chronopotentiometry experiments on the solutions used in this example yielded nearly identical polarization curves for the baseline formulation and the formulations containing TPB:0.5 EO, TPB:1.0 EO and TPB:1.5 EO.

### Example 14

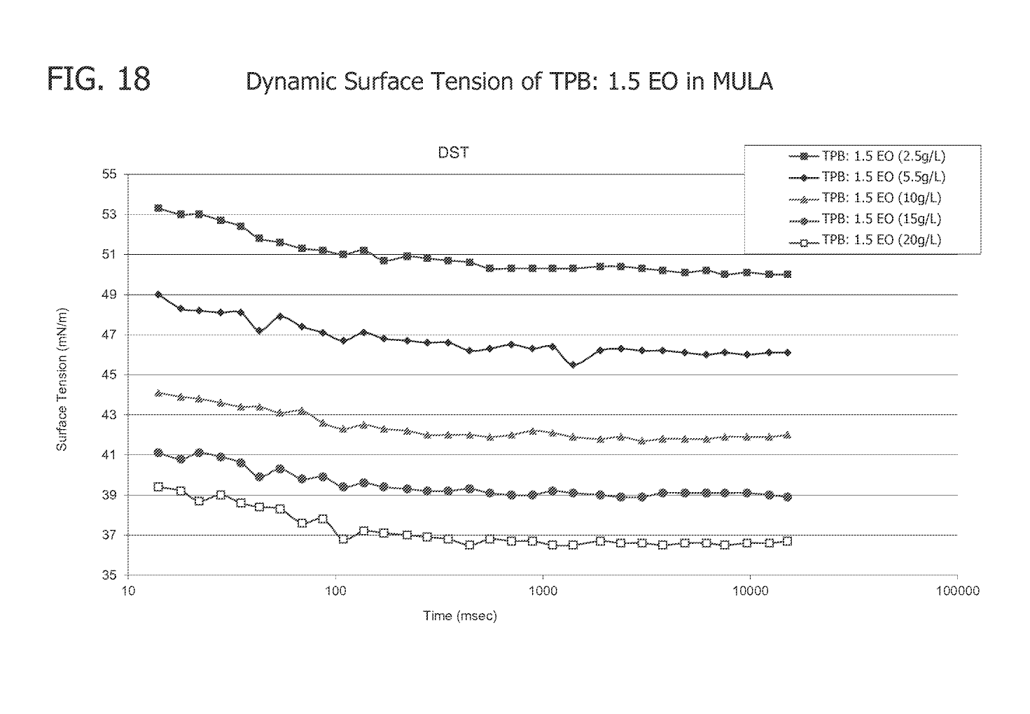

Dynamic surface tension tests were conducted on solutions containing TPB:1.5 EO in a MULA solution that contained copper sulfate (40 g/L Cu⁺⁺), sulfuric acid (10 g/L) and chloride ion (50 ppm). Separate solutions were tested which contained TPB:1.5 EO in concentrations of 2.5 g/L, 5 g/L, 10 g/L, 15 g/L and 20 g/L, respectively. Plots of dynamic surface tension vs. surface age are shown in FIG. 18.

### Example 15

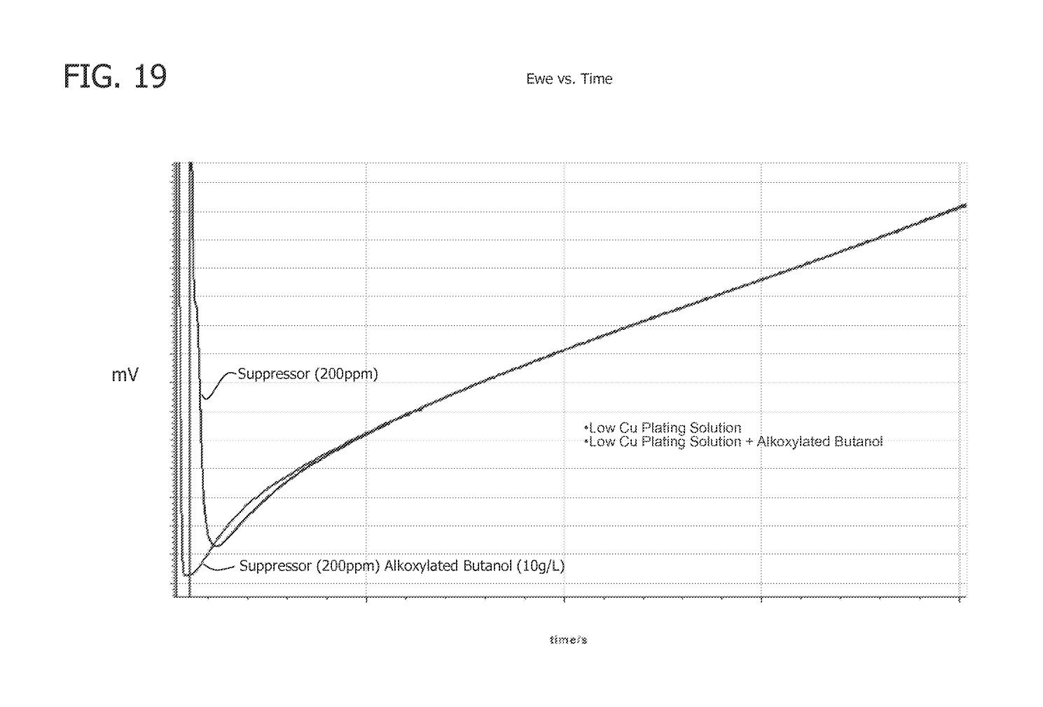

A low copper makeup solution was prepared consisting of copper sulfate (5 g/L Cu⁺⁺), sulfuric acid (10 g/L) and chloride ion (50 ppm). A plating solution was prepared by adding SPS (63 mg/L), a suppressor (200 ppm), and a wetter comprising butyl alcohol alkoxylated with a polyalkylene oxide chain containing equal molar proportions of propylene oxide and ethylene oxide repeat units and having a molecular weight in the range of 270, principally HO-(EO)₂(PO)₂Bu. Chronopotentiometry tests conducted on both the low copper solution alone and the low copper solution with wetter indicated that polarization strength was increased by 10 my in the presence of the wetter, as shown in FIG. 19 wherein the polarization curves are reproduced. Adsorption time was also quicker than the solution without the wetter, and disruption rate (slope of potential curve after maximum voltage is reached) was similar in both solutions.

### Example 16

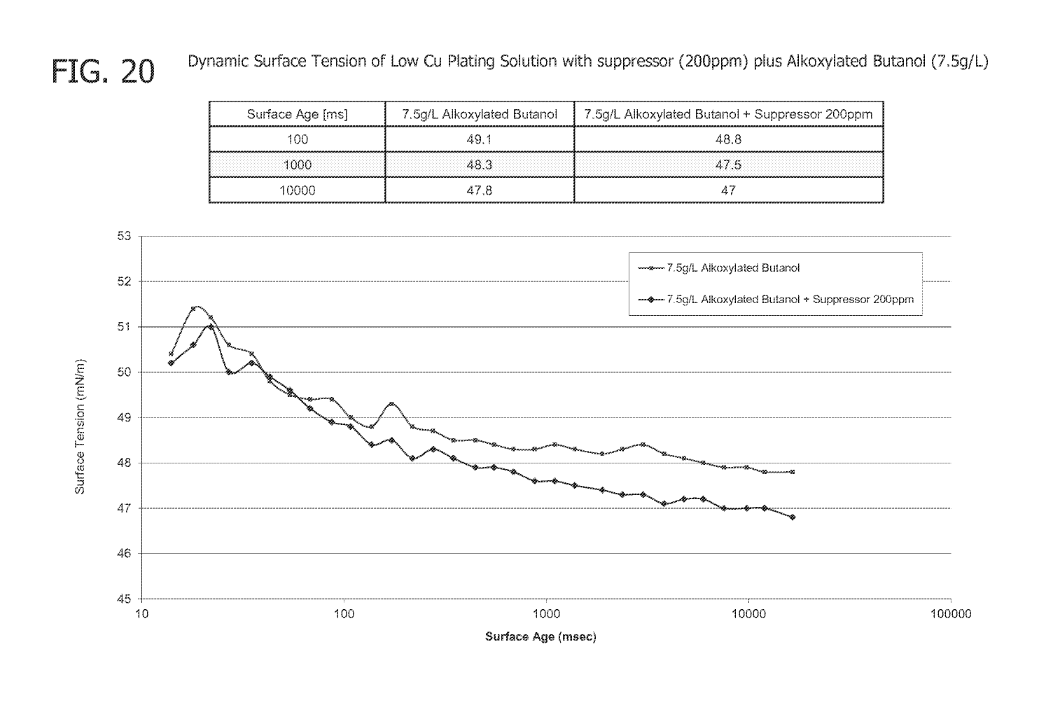

Two compositions were prepared containing the alkoxylated butanol described in Example 15 (7.5 g/L). To one solution an alkoxylated amine suppressor was added in a concentration of 200 ppm. Dynamic surface tension tests were conducted on each of these solutions. The results are plotted in FIG. 20.

### Example 17

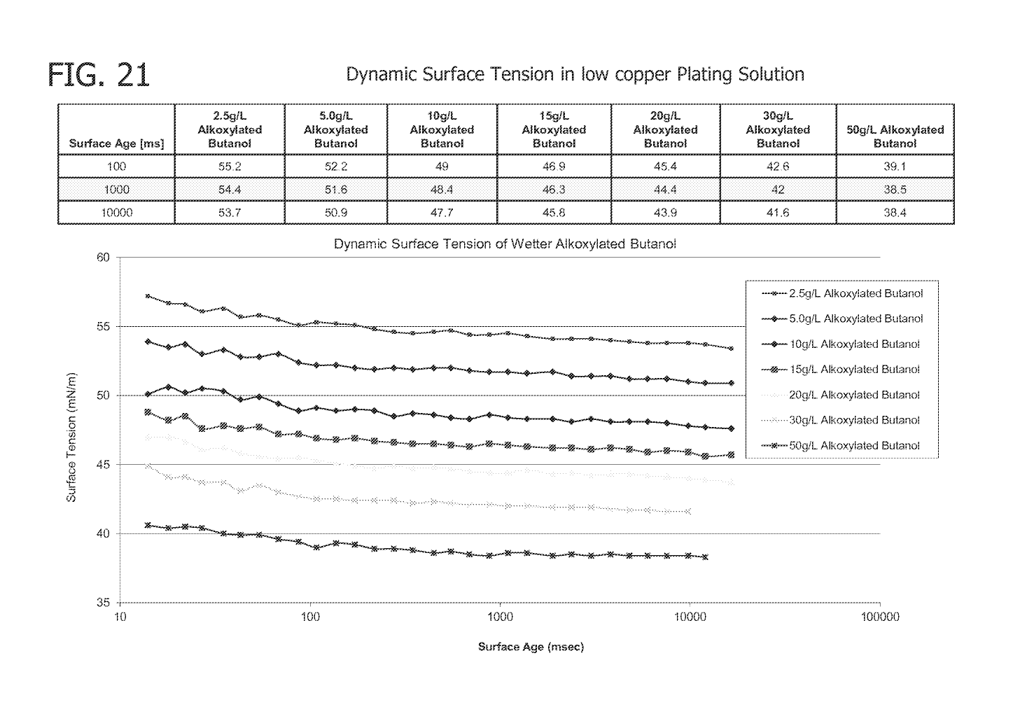

Dynamic surface tension tests were conducted on solutions containing the alkoxylated butanol of Example 15 in a low copper electrolyte solution that contained copper sulfate (5 g/L Cu⁺⁺), sulfuric acid (10 g/L) and chloride ion (50 ppm). Separate solutions were tested which contained the alkoxylated butanol in concentrations of 2.5 g/L, 5 g/L, 10 g/L, 15 g/L, 20 g/L, 30 g/L and 50 g/L, respectively. Plots of dynamic surface tension vs. time are shown in FIG. 21.

### Example 18

Tests were conducted comparing the solubility of TPB and modified hydrotropes prepared by reacting TPB with 0.5, 1.0 and 1.5 moles ethylene oxide, respectively, in a low copper MULA bath comprising copper sulfate (5 g/L Cu⁺⁺), sulfuric acid (10 g/L), and chloride ion (50 ppm). When a mixture of 10 g/L TPB and the low copper electrolyte was agitated at 750 rpm and room temperature, it took longer than 60 minutes for the TPB to fully dissolve. When mixtures of the electrolyte and 10 g/L of the reaction products of TPB and ethylene oxide were agitated under the same conditions, the TPB:0.5 EO product was completely dissolved within 4 minutes, and each of the TPB: 1.0 EO and TPB:1.5 EO products was fully dissolved within 2 minutes.

Cloud point measurements were made on formulations containing varying concentrations TPB and formulations containing varying amounts of the reaction product of TPB and 1.5 moles ethylene oxide. Observed cloud points are summarized in Table 4:

TABLE 4
Cloud Point (° C.) in Low Cu Plating Bath

| Concentration (g/L) | TPB | TPB:1.5 EO |
|---|---|---|
| 2.5 | >90 | >90 |
| 5 | >90 | >90 |
| 7.5 | 60 | |
| 10 | 48 | 67 |
| 15 | 44 | |
| 20 | | 50 |

Foam height tests were conducted on an electrolytic plating solution comprising the low copper electrolyte and an alkoxylated amine suppressor. Comparative measurements of foam height were conducted on the same plating solution to which had been added 7.5 g/L and 10 g/L, respectively, of the reaction product of TPB and 1.5 moles ethylene oxide. Results of these tests are set forth in Table 5.

TABLE 5
Foam Height & Retention Time in Low Cu Plating Bath

| | Foam | Retention |
|---|---|---|
| Additive | Height (cm) | Time (sec) |
| alkoxylated amine suppressor | 40 | 21 |
| (200 ppm) | | |
| alkoxylated amine suppressor | 23 | 9 |
| (200 ppm) + TPB:1.5EO (10 g/L) | | |
| (200 ppm) + alkoxylated amine | 22 | 8 |
| suppressor (7.5 g/L TPB) | | |

### Example 19

Dynamic surface tension tests were conducted on eight different solutions: (1) a low acid MULA containing an alkoxylated amine suppressor (200 ppm); (2) a low copper electrolyte containing an alkoxylated amine suppressor (200 ppm); (3) a MULA containing a suppressor comprising a mixture of an alkoxylated amine (200 ppm) and an EO/PO co-block polymer (300 ppm); (4) a low copper electrolyte containing the same suppressor mixture as solution 3; (5) a low acid MULA containing the same alkoxylated amine suppressor mixture as in solution 3 with an alternative EO/PO co-block polymer (300 ppm); (6) a low copper electrolyte containing the same suppressor mixture as solution 5; (7) a low acid MULA containing TPP (20 g/L); and (8) a low acid MULA containing an alkoxylated amine suppressor (200 ppm) and TPP (20 g/L).

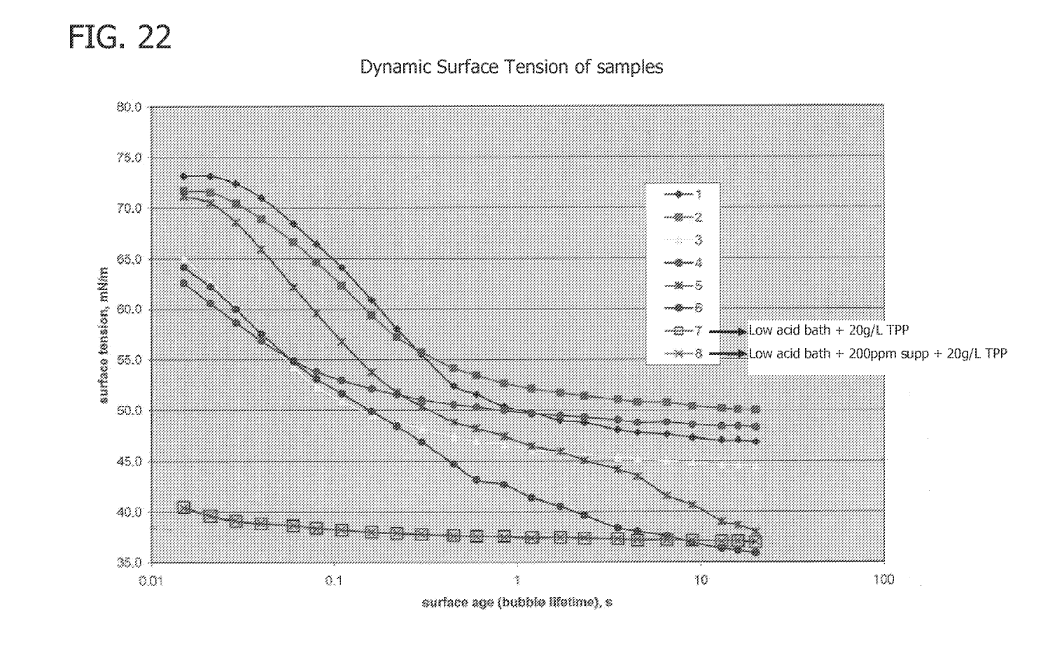

FIG. 22 plots dynamic surface tension vs. surface age for each of the formulations of this example. It will be seen that the dynamic surface tension curve for solution 8, which contained both a suppressor and TPP in a low acid MULA is congruent with the curve for solution 7 which contained only TPP in a low acid MULA. Each of solutions 7 and 8 exhibited much lower dynamic surface tension than any of the other solutions

Having described the invention in detail, it will be apparent that modifications and variations are possible without departing from the scope of the invention defined in the appended claims.

When introducing elements of the present invention or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the invention are achieved and other advantageous results attained.

As various changes could be made in the above compositions and methods without departing from the scope of the invention, it is intended that all matter contained in the above description and shown in the accompanying drawings shall be interpreted as illustrative and not in a limiting sense.

1. A n aqueous composition for electroplating copper comprising a source of copper ions and one or more alkylene or polyalkylene glycol ethers having the following general Structure (1) or (2):
R¹O[CH₂CHR²O]ₙR³ Structure (1)
R¹O[CH₂CHR²O]ₙ[CH₂CHR⁴O]ₘR³ Structure (2)
wherein R¹ is a substituted or unsubstituted alkyl group having 1 to 6 carbon atoms, a cycloalkyl group, or an aryl group; R² is H or is a substituted or unsubstituted alkyl group having from 1 to 3 carbon atoms; R⁴ is H or a substituted or unsubstituted alkyl group having from 1 to 3 carbon atoms, R⁴ being different from R²; R³ is H or —CH₂CH(OH)CH₂—OH, and n and m are such that the alkylene or polyalkylene glycol ether is soluble in the aqueous phase and has molecular weight not greater than about 500.

2. A composition as set forth in claim 1 wherein R² is a substituted or unsubstituted alkyl group having 1 to 3 carbon atoms.

3. A composition as set forth in claim 2 wherein R⁴ is H

4. A composition as set forth in claim 1, wherein n is an integer from 1 to 5, m is an integer from 1 to 3, and m+n is an integer from 1 to 6.

5. A composition as set forth in claim 3, wherein n is an integer from 1 to 4 or from 2 to 4.

6. A composition as set forth in claim 3, wherein n is an integer from 1 to 4, m is an integer from 1 to 2 and m+n is an integer from 3 to 5.

7. A composition as set forth in claim 1, wherein the sum of the concentrations of alkylene or polyalkylene glycol ethers is between about 1 and about 20 g/L, or between about 3 and about 20 g/L or between about 5 and about 20 g/L, or between about 5 and about 15 g/L, or between about 5 and about 10 g/L.

8. A composition as set forth in claim 1, wherein R¹ is selected from the group consisting of substituted and unsubstituted alkyl and substituted and unsubstituted cycloalkyl.

9. A composition as set forth in claim 8 wherein R¹ comprises substituted or unsubstituted alkyl.

10. A composition of claim 1, wherein said glycol ether corresponds to general structure (1)
wherein R¹ is substituted or unsubstituted alkyl group having from 1 to 6 carbon atoms;
R² is methyl;
R⁴ is hydrogen; and
n is an integer between 1 and 3, inclusive.

11. A composition as set forth in claim 2 comprising a mixture of plural Structure (2) species, or of structure (1) and structure (2) species, wherein R⁴ is H, n is 2 or 3 and m*, the number average of values of m in the mixture, is between about 0.2 and about 0.8, or between about 0.8 and about 1.2, or between about 1.2 and about 1.8.

12. A composition as set forth in claim 11 wherein R² is methyl and R¹ is substituted or unsubstituted alkyl having 1 to 6 carbon atoms.

13. The composition as set forth in claim 1, further comprising a suppressor compound.

14. A composition as set forth in claim 13 wherein said suppressor is present in a concentration effective for promoting superfilling of submicron interconnect features in a semiconductor integrated circuit device substrate.

15. A composition as set forth in claim 12 wherein said suppressor comprises a polyether bonded to the nitrogen of a nitrogen-containing species, said polyether comprising a combination of propylene oxide (PO) repeat units and ethylene oxide (EO) repeat units in a PO:EO ratio between about 1:9 and about 9:1, said suppressor having a molecular weight between 1000 and 30,000.

16. A composition as set forth in claim 15 wherein the ratio of PO:EO repeat units is between about 1.5 and 8:5, or between 2:8 and about 8:2, or between about 3:7 and about 7:3.

17. A composition as set forth in claim 18, wherein the concentration of said suppressor in said electrolytic plating solution is between about 40 and about 250 mg/L.

18. A composition as set forth in claim 13, wherein the concentration of said suppressor in said electrolytic plating solution is between about 10 and about 400 mg/L.

19. A composition as set forth in claim 1, wherein said composition has a dynamic surface tension at 25° C. no greater than about 55 dynes/cm, a static surface tension at 25° C. no greater than about 50 dynes/cm and a cloud point of at least 30° C.

20. A composition as set forth in claim 19 having a static surface tension at 25° C. of not greater than 45 dynes/cm.

21. A composition as set forth in claim 20 having a dynamic surface tension not greater than about 45 dynes/cm.

22. A process for electrodeposition of copper on a substrate comprising a copper-based or cobalt-based surface, the process comprising:
establishing an electrolytic circuit comprising a power source, an anode in contact with an electrodeposition solution and a cathode comprising the substrate surface and in contact with said electrodeposition solution; and
passing an electrolytic current through said circuit to deposit copper on said cathode;
wherein said electrodeposition solution comprises the aqueous composition of claim 1.

23. A process as set forth in claim 22 wherein said substrate surface comprises a copper-based or cobalt-based seed layer on a supporting structure selected from the group consisting of a semiconductor having submicron features to be filled with electrodeposited copper, a through silicon via, or a printed wiring board.

24. A process as set forth in claim 23 wherein said layer comprises Cu or Co.

25. A process as set forth in claim 23 comprising damascene plating of copper in submicron interconnects of a semiconductor device.

26. A process as set forth in claim 25 wherein said substrate comprises submicron-sized interconnect features having aspect ratio of at least about 3:1 or at least about 4:1, or at least about 5:1, or at least about 8:1.

27. A process a set forth in claim 26 wherein said substrate comprises submicron features having a combination of an aspect ratio of ≧4:1, ≧5:1 or ≧8:1 and an entry dimension less than about 100 nm.

28. A process as set forth in claim 26 wherein said substrate comprises submicron features having an entry dimension between about 20 and about 50 nm.

29. An aqueous composition for electroplating copper comprising a source of copper ions and one or more alkylene or polyalkylene glycol monoethers having the following general Structure (4):
R¹O[CH₂CR⁴O]ₘ[CH₂CHR²O]ₙ[CH₂CH₂O]ₚR³ Structure (8)
wherein R¹ is a substituted or unsubstituted alkyl group having 1 to 6 carbon atoms, a cycloalkyl group, or an aryl group; R² is a substituted or unsubstituted alkyl group having from 1 to 3 carbon atoms; R⁴ is H or a substituted or unsubstituted alkyl group having from 1 to 3 carbon atoms, R⁴ is different from R², R3 is H or CH₂CH(OH)CH₂—OH, and n, m and p are such that the alkylene or polyalkylene glycol ether is soluble in the aqueous phase and has molecular weight not greater than about 500.

30. An aqueous composition as set forth in claim 29 wherein R⁴ is H.

31. An aqueous composition as set forth in claim 28 comprising a mixture of species of structure (4) wherein m*, the number average value of n*, the number average value of n, and p*, the number average value of p are such that the number average molecular weight of the mixture is less than 500.

32. An aqueous composition as set forth in claim 31 wherein p* is between 0.5 and 2.0 or between 1.0 and 2.0.

33. An aqueous composition as set forth in claim 31 wherein p* is between 0.2 and 0.8, or between 0.8 and 1.2, or between 1.2 and 2.0.
